(19) United States
(12) Patent Application Publication
(10) Pub. No.: US 2024/0159795 A1
(43) Pub. Date: May 16, 2024

(54) ELECTRICALLY CONDUCTIVE CONTACT PIN

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Chang Hee HONG, Gyeonggi-do (KR)

(73) Assignee: POINT ENGINEERING CO., LTD., Chungcheongnam-do (KR)

(21) Appl. No.: 18/284,066

(22) PCT Filed: Mar. 22, 2022
(86) PCT No.: PCT/KR2022/003991

§ 371 Date: Sep. 25, 2023

(30) Foreign Application Priority Data
Mar. 31, 2021 (KR) 10-2021-0042208
May 28, 2021 (KR) 10-2021-0069523

(51) Int. Cl. G01R 1/04

(52) U.S. Cl. CPC G01R 1/0466

(57) ABSTRACT

Proposed is an electrically conductive contact pin, including a pin portion including a first contact portion, a second contact portion, and an elastic portion between the first contact portion and the second contact portion, a fixing portion provided outside the pin portion, and a connecting portion provided between the pin portion and the fixing portion to connect the pin portion and the fixing portion to each other.

### TECHNICAL FIELD

The present disclosure relates to an electrically conductive contact pin.

### BACKGROUND ART

A test for electrical characteristics of a semiconductor device is performed by approaching an inspection object (semiconductor wafer or semiconductor package) to an inspection apparatus having a plurality of electrically conductive contact pins and then bringing the respective electrically conductive contact pins into contact with corresponding external terminals (solder balls or bumps) on the inspection object. Examples of inspection apparatuses include, but are not limited to, probe cards or test sockets.

Conventional test sockets include a pogo-type socket and a rubber-type socket.

An electrically conductive contact pin (hereinafter referred to as a “pogo-type socket pin”) used in the pogo-type test socket includes a pin portion and a barrel accommodating the pin portion. The pin portion is provided with a spring member between plungers at opposite ends of the pin portion to enable application of required contact pressure and shock absorption at a contact position. In order for the pin portion to slide within the barrel, a gap has to exist between an outer surface of the pin portion and an inner surface of the barrel. However, since the pogo-type socket pin is used by separately manufacturing the barrel and the pin portion and then assembling them together, the gap between the outer surface of the pin portion and the inner surface of the barrel is increased more than necessary, so it is impossible to precisely manage the gap. Therefore, electrical signals are lost and distorted in the process of being transferred to the barrel via the opposite plungers, causing a problem in that contact stability is not constant. In addition, the pin portion has a pointed tip portion to increase the contact effect with an inspection object. The pointed tip portion generates a mark or a groove due to press-contact on an external terminal of the inspection object after inspection. The loss of the contact shape of the external terminal causes an error in vision test and lowers the reliability of the external terminal in a subsequent process such as soldering.

Meanwhile, an electrically conductive contact pin (hereinafter referred to as a “rubber-type socket pin”) used in a rubber-type test socket has a structure in which conductive microballs are disposed inside a silicon rubber made of a rubber material. When stress is applied by placing an inspection object (e.g., a semiconductor package) and closing the socket, conductive microballs made of gold strongly press each other and increase conductivity, making the microballs electrically connected. However, the rubber-type socket pin has a problem in that contact stability is secured only when the socket pin is pressed with an excessive pressing force.

Meanwhile, with the advancement and high integration of semiconductor technology, the pitch of the external terminals of the inspection object has become narrower. In the case of the rubber-type socket pin, the socket pin is produced by preparing a molding material in which conductive particles are distributed in a fluid elastic material, inserting the molding material into a predetermined mold, and applying a magnetic field in the thickness direction to arrange the conductive particles in the thickness direction. Due to this manufacturing technique, when the distance between magnetic fields is narrowed, the conductive particles are irregularly oriented and a signal flows in the plane direction. Thus, the conventional rubber-type socket pin has limitations in responding to the trend toward narrow pitch technology.

In addition, since the pogo-type socket pin is used by separately manufacturing the barrel and the pin portion and then assembling them together, it is difficult to manufacture the socket pin in a small size. Thus, the pogo-type socket pin also has limitations in responding to the trend toward narrow pitch technology.

Accordingly, there is a need to develop a new type of electrically conductive contact pin that can improve the inspection reliability of inspection for an inspection object to enable compliance with the recent technology trend.

### DOCUMENTS OF RELATED ART

### Patent Documents

(Patent Document 1) Korean Patent No. 10-0659944
(Patent Document 2) Korean Patent No. 10-0952712

### DISCLOSURE

### Technical Problem

Accordingly, the present disclosure has been made keeping in mind the above problems occurring in the related art, and an objective of the present disclosure is to provide an electrically conductive contact pin that improves inspection reliability for an inspection object.

### Technical Solution

In order to accomplish the above objective, according to one aspect of the present disclosure, there is provided an electrically conductive contact pin, including: a pin portion including a first contact portion, a second contact portion, and an elastic portion between the first contact portion and the second contact portion; a fixing portion provided outside the pin portion; and a connecting portion provided between the pin portion and the fixing portion to connect the pin portion and the fixing portion to each other.

In addition, the pin portion, the fixing portion, and the connecting portion may be integrally provided with each other.

In addition, the electrically conductive contact pin may be elastically deformable in a length direction and at the same time elastically deformable in a width direction.

In addition, the pin portion may be relatively displaceable with respect to the fixing portion.

In addition, the first contact portion may include: a first lower portion contact portion brought into contact with a lower portion of a contact object; and a first side portion contact portion brought into contact with a side portion of the contact object.

In addition, the first contact portion may include a first side portion contact portion brought into contact with a side portion of a contact object.

In addition, the connecting portion may be formed to extend in the same length direction as a length direction of the fixing portion.

In addition, the connecting portion may be relatively movable with respect to the fixing portion so that a separation space between the fixing portion and the connecting portion is changed.

In addition, the connecting portion may be connected to a lower end of the fixing portion.

In addition, the connecting portion may be connected to at least a part of the pin portion and may be connected to a lower end of the fixing portion to connect the pin portion and the fixing portion to each other.

In addition, the electrically conductive contact pin may further include: a boundary portion provided in a width direction. Here, the first contact portion may be connected to an upper portion of the boundary portion, the elastic portion may be connected to a lower portion of the boundary portion, and the connecting portion may be connected to each side of the boundary portion.

In addition, the fixing portion may include a protrusion protruding outwardly.

In addition, at least a part of the elastic portion may protrude outwardly below a lower end of the fixing portion, and at least a part of the first contact portion may protrude outwardly upwardly above an upper end of the fixing portion.

In addition, the elastic portion may be formed by alternately connecting a plurality of straight portions and a plurality of curved portions, and a distance between two straight portions connected to one curved portion may not exceed a distance between opposite sides of the one curved portion.

Meanwhile, according to another aspect of the present disclosure, there is provided an electrically conductive contact pin, including: a pin portion including a first contact portion, a second contact portion, and an elastic portion between the first contact portion and the second contact portion. Here, the first contact portion may include: a first lower portion contact portion; and a first side portion contact portion provided outside the first lower portion contact portion.

In addition, the first side portion contact portion may be formed to extend in a length direction of the electrically conductive contact pin.

In addition, the first lower portion contact portion may include: a neck portion; and a lower surface support portion connected to the neck portion and brought into contact with a contact object.

In addition, the electrically conductive contact pin may further include: a boundary portion having an upper portion to which the first contact portion is connected and a lower portion to which the elastic portion is connected, and provided in the form of a plate in a width direction. Here, the first side portion contact portion may be connected to the boundary portion and may be formed to extend upwardly.

In addition, the first side portion contact portion may include a guide portion inclined outwardly.

In addition, the first side portion contact portion may include a pair of first side portion contact portions, and the pair of first side portion contact portions may be elastically deformable so that a separation distance between the pair of first side portion contact portions decreases.

Meanwhile, according to another aspect of the present disclosure, there is provided an electrically conductive contact pin having an overall length in a length direction, an overall thickness in a thickness direction perpendicular to the length direction, and an overall width in a width direction perpendicular to the length direction. Here, plates are integrally connected to each other form the electrically conductive contact pin, and an actual width of the plates constituting the electrically conductive contact pin and the overall thickness may have a ratio in a range of 1:5 to 1:30.

In addition, the overall thickness and the overall length may have a ratio in a range of 1:3 to 1:9, and the overall thickness and the overall width may have a ratio in a range of 1:1 to 1:5.

In addition, the actual width of the plates may be in a range of 5 μm to 15 μm, and the overall thickness may be in a range of 70 μm to 200 μm.

In addition, the overall length may be in a range of 300 μm to 2 mm.

Meanwhile, according to another aspect of the present disclosure, there is provided an electrically conductive contact pin provided as a single body, the electrically conductive contact pin including: a pair of fixing portions formed in the form of a plate extending in a length direction; a pair of connecting portions each of which is connected through a connection portion to a lower end of each of the fixing portions and formed in the form of a plate extending in the length direction; a boundary portion connected to the connecting portions and formed in the form of a plate extending in a width direction; a first contact portion connected to an upper portion of the boundary portion; an elastic portion connected to a lower portion of the boundary portion; and a second contact portion connected to the elastic portion.

In addition, the first contact portion may include a first side portion contact portion brought into contact with a side surface of a contact object, and the first side portion contact portion may be elastically deformable in the width direction.

In addition, the electrically conductive contact pin may be formed by stacking a plurality of metal layers.

In addition, at least one of the fixing portions, the connecting portions, the boundary portion, the first contact portion, the elastic portion, and the second contact portion may differ in at least one of material, number, and content of metal layers compared to another at least one thereof.

In addition, the plurality of metal layers may include a first metal and a second metal stacked alternately, and the second metal may not further protrude than the first metal in at least a partial surface area of the electrically conductive contact pin.

### Advantageous Effects

An electrically conductive contact pin according to the present disclosure can improve inspection reliability for an inspection object.

### DESCRIPTION OF DRAWINGS

FIG. 1 is a plan view illustrating an electrically conductive contact pin according to a first embodiment of the present disclosure.

FIG. 2 illustrates left and right perspective views illustrating the electrically conductive contact pin according to the first embodiment of the present disclosure.

FIG. 3 is a right perspective view illustrating a state in which an external terminal of an inspection object is inserted into an upper portion of the electrically conductive contact pin according to the first embodiment of the present disclosure.

FIG. 4 is a view illustrating a state before electrically conductive contact pins according to the first embodiment of the present disclosure are inspected in a state of being installed on a housing plate.

FIG. 5 is a plan view illustrating an electrically conductive contact pin according to a second embodiment of the present disclosure.

FIG. 6 is a perspective view illustrating the electrically conductive contact pin according to the second embodiment of the present disclosure.

FIG. 7 is a plan view 8 is a partially enlarged view.

FIG. 8 is a partially enlarged view illustrating the electrically conductive contact pin according to the third embodiment of the present disclosure.

FIG. 9 is a view illustrating a state before electrically conductive contact pins according to the third embodiment of the present are inspected in a state of being installed in a housing plate.

FIG. 10 is a plan view illustrating an electrically conductive contact pin according to a fourth embodiment of the present disclosure.

FIG. 11 is a perspective view illustrating the electrically conductive contact pin according to the fourth embodiment of the present disclosure.

FIG. 12 is a plan view illustrating a state in which an external terminal is connected to the electrically conductive contact pin according to the fourth embodiment of the present disclosure.

FIG. 13 is a plan view illustrating an electrically conductive contact pin according to a fifth embodiment of the present disclosure.

FIG. 14 is a view illustrating a state before electrically conductive contact pins according to the fifth embodiment of the present disclosure are inspected in a state of being installed in a housing plate.

FIG. 15 is a view illustrating a state in which the electrically conductive contact pins according to the fifth embodiment of the present disclosure are inspected in a state of being installed in the housing plate.

FIG. 16 is a plan view illustrating an electrically conductive contact pin according to a sixth embodiment of the present disclosure.

FIG. 17 is a plan view illustrating an electrically conductive contact pin according to a seventh embodiment of the present disclosure.

FIG. 18 is a plan view illustrating an electrically conductive contact pin according to an eighth embodiment of the present disclosure.

FIG. 19 is a plan view illustrating an electrically conductive contact pin according to a ninth embodiment of the present disclosure.

FIG. 20 is a plan view illustrating an electrically conductive contact pin according to a tenth embodiment of the present disclosure.

FIG. 21 is a perspective view illustrating an electrically conductive contact pin according to an eleventh embodiment of the present disclosure.

FIG. 22 is a perspective view illustrating an electrically conductive contact pin according to a twelfth embodiment of the present disclosure.

FIGS. 23A to 23D are plan views illustrating modified examples of a first contact portion according to embodiments of the present disclosure.

FIG. 24 is a view illustrating a process for manufacturing the electrically conductive contact pins according to the embodiments of the present disclosure.

FIG. 25 is a view illustrating a side surface of each of the electrically conductive contact pins according to the embodiments of the present disclosure.

### MODE FOR INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are clearly intended for the purpose of understanding the concept of the present disclosure, and one should understand that the present disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, thicknesses of films and regions in the figures may be exaggerated. Therefore, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. The technical terms used herein are for the purpose of describing particular embodiments only and should not be construed as limiting the present disclosure. As used herein, the singular forms are intended to include the plural forms as well, unless the context clearly indicates otherwise. It will be further understood that the terms “comprise”, “include”, “have”, etc. when used herein, specify the presence of stated features, integers, steps, operations, elements, components, and/or combinations thereof but do not preclude the presence or addition of one or more other features, integers, steps, operations, elements, components, and/or combinations thereof.

Hereinafter, exemplary embodiments of the present disclosure will be described in detail with reference to the accompanying drawings. Wherever possible, the same reference numerals will be used throughout different embodiments and the description to refer to the same or like elements or parts. In addition, the configuration and operation already described in other embodiments will be omitted for convenience.

An electrically conductive contact pin 10 according to an embodiment of the present disclosure is provided in an inspection apparatus and is used to transmit electrical signals by making electrical and physical contact with an inspection object 20. The inspection apparatus may be an inspection apparatus used in a semiconductor manufacturing process, for example, a probe card or a test socket. The electrically conductive contact pin 10 may be a probe pin provided in the probe card or a socket pin provided in the test socket. In the following, the socket pin will be exemplified and described as an example of the electrically conductive contact pin 10. However, the electrically conductive contact pin 10 according to the exemplary embodiment of the present disclosure is not limited thereto and includes any pin for checking whether the inspection object 20 is defective by applying electricity.

Hereinafter, first to twelfth embodiments will be separately described, but embodiments in which the elements of each embodiment are combined are also included in exemplary embodiments of the present disclosure.

### First Embodiment

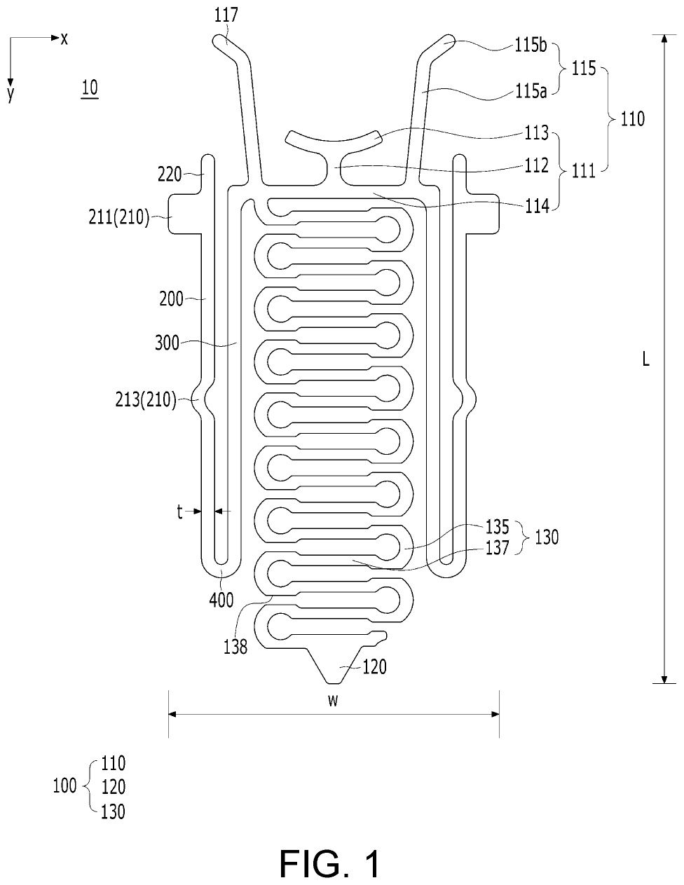

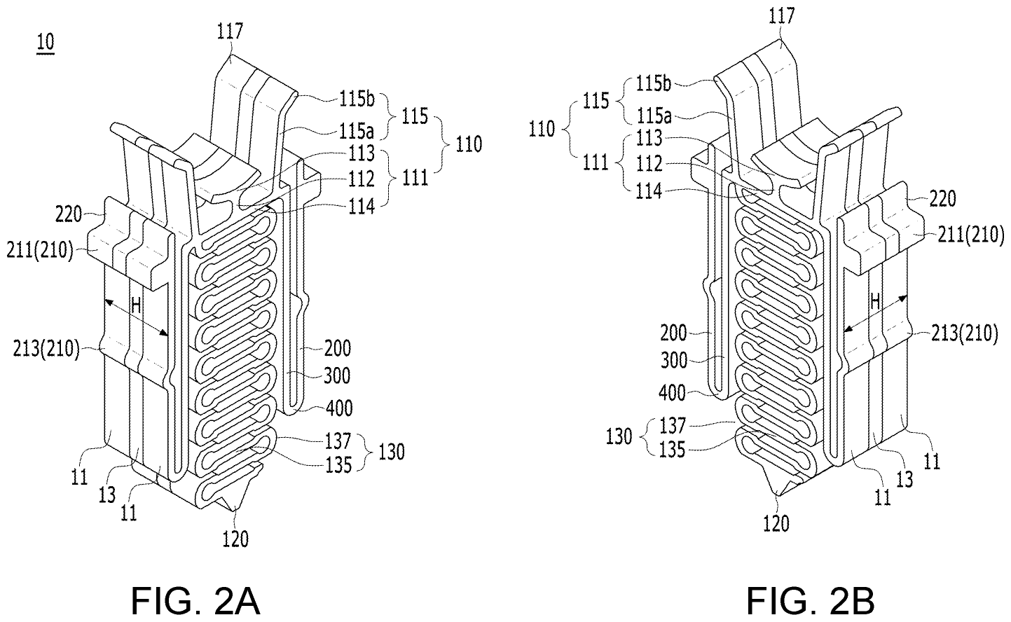

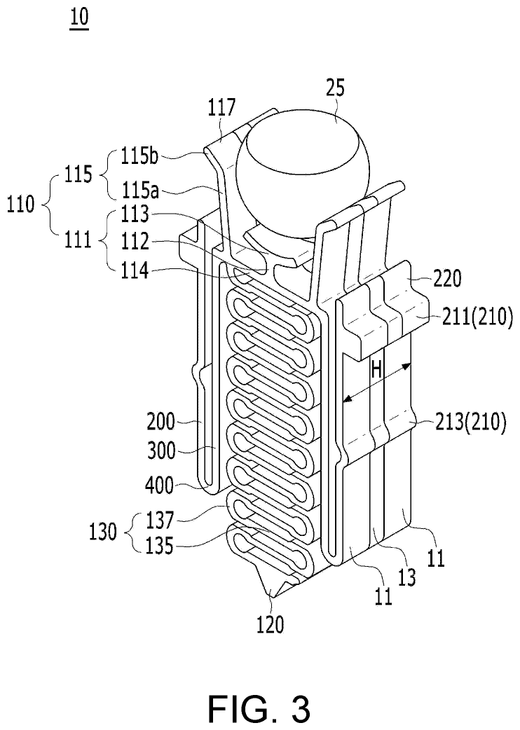

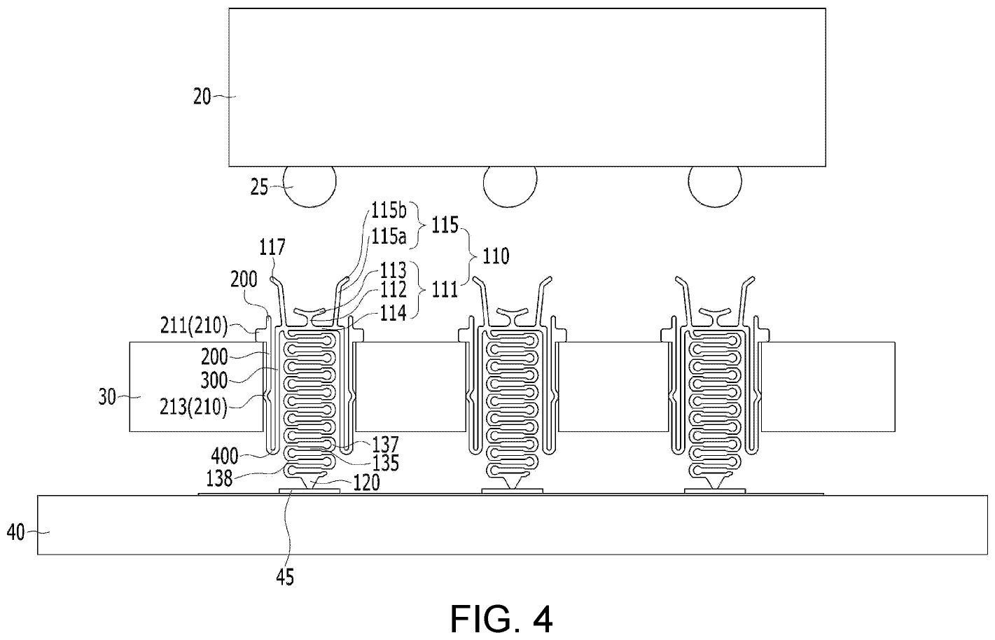

Hereinafter, an electrically conductive contact pin 10 according to the first embodiment of the present disclosure will be described with reference to FIGS. 1 to 4. FIG. 1 is a plan view illustrating the electrically conductive contact pin 10 according to the first embodiment of the present disclosure. FIG. 2 illustrates left and right perspective views illustrating the electrically conductive contact pin 10 according to the first embodiment of the present disclosure. FIG. 3 is a right perspective view illustrating a state in which an external terminal 25 of the inspection object 20 is inserted into an upper portion of the electrically conductive contact pin 10 according to the first embodiment of the present disclosure. FIG. 4 is a view illustrating a state before electrically conductive contact pins 10 according to the first embodiment of the present disclosure are inspected in a state of being installed on a housing plate 30.

In FIG. 1, the x direction is the width direction of the electrically conductive contact pin 10, the y direction is the length direction of the electrically conductive contact pin 10, and the z direction (not illustrated) is the thickness direction of the electrically conductive contact pin 10.

The electrically conductive contact pin 10 includes a pin portion 100, a fixing portion 200, and a connecting portion 300.

The pin portion 100 includes a first contact portion 110 at an upper portion thereof, a second contact portion 120 at a lower portion thereof, and an elastic portion 130 between the first contact portion 110 and the second contact portion 120.

The fixing portion 200 serves to fix the electrically conductive assembly 10 to a housing plate 30. After the electrically conductive contact pin 10 is installed in the housing plate 30, the electrically conductive contact pin 10 remains fixed to the housing plate 30.

The connecting portion 300 is provided between the pin portion 100 and the fixing portion 200 in the width direction of the electrically conductive contact pin 10 and connects the pin portion 100 and the fixing portion 200 to each other.

The pin portion 100, the fixing portion 200, and the connecting portion 300 are integrally provided with each other. The pin portion 100, the fixing portion 200, and the connecting portion 300 are manufactured simultaneously through a plating process. As described below, the electrically conductive contact pin 10 is formed using a mold 1000 having an inner space 1100 by filling the inner space 1100 with a metal material through electroplating. Thus, the pin portion 100, the fixing portion 200, and the connecting portion 300 are integrally manufactured to form a single body. A conventional electrically conductive contact pin is provided by separately manufacturing a barrel and a pin portion and then assembling them. However, the electrically conductive contact pin 10 according to the embodiment of the present disclosure has a structural difference in that it is provided as a single body by simultaneously manufacturing the pin portion 100, the fixing portion 200, and the connecting portion through the plating process.

The electrically conductive contact pin 10 has a uniform cross-sectional shape in the thickness direction. In other words, the uniform cross-sectional shape is formed by extending in the thickness direction.

A plurality of metal layers are stacked in the thickness direction of the electrically conductive contact pin 10. The plurality of metal layers include a first metal 11 and a second metal 13.

The first metal 11 is a metal having relatively high wear resistance compared to the second metal 13, and may be selected from the group consisting of rhodium (Rd), platinum (Pt), iridium (Ir), palladium, and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn), a nickel-cobalt (NiCo), and a nickel-tungsten (NiW) alloy. However, the present disclosure is not limited thereto.

The second metal 13 is a metal having relatively high electrical conductivity compared to the first metal 11, and may be selected from the group consisting of copper (Cu), silver (Ag), gold (Au), and an alloy of these metals. However, the present disclosure is not limited thereto.

The first metal 11 is provided on each of a lower surface and an upper surface of the electrically conductive contact pin 10 in the thickness direction, and the second metal 13 is provided between the respective first metals 11. For example, the electrically conductive contact pin 10 may be provided by sequentially stacking the first metal 11, the second metal 13, and the first metal 11, and the number of stacked layers may be at least three.

The first metal 11 and the second metal 13 are alternately stacked, and the second metal 13 is provided between the first metals 11 at a position brought into contact with the external terminal 25 of the inspection object 20.

The plurality of metal layers constituting the electrically conductive contact pin 10 may differ in material and/or content for each configuration of the electrically conductive contact pin 10. For example, at least one of the pin portion 100, the fixing portion 200, and the connecting portion 300 may differ in at least one of material, number, and content of the metal layers compared to another at least one thereof. Alternatively, at least one of the fixing portion 200, the connecting portion 300, a boundary portion 114, the first contact portion 110, the elastic portion 130, and the second contact portion 120 may differ in at least one of the material, number, and content of the metal layers compared to another at least one thereof. Each configuration may have a different function. By varying at least one of the material, number, and content of the metal layers for each configuration according to the function, the physical or electrical properties of each configuration may be varied. The content of the second metal 13 may be high in a configuration in which a rapid current flow is required, and the content of the first metal 11 may be high in a configuration in which sufficient elastic deformation strength is required. In addition, in a part of the configurations, a plurality of metal layers may not be stacked and only one metal layer may be formed. For example, the second contact portion 120 may be composed of only the first metal 11 to improve wear resistance.

The electrically conductive contact pin 10 is elastically deformable in the length direction and at the same time elastically deformable in the width direction. The pin portion 100 is elastically deformable in the length direction with respect to the fixing portion 200. The pin portion 100 is relatively displaceable in the width direction with respect to the fixing portion 200.

The pin portion 100 includes the first contact portion 110, the second contact portion 120, and the elastic portion 130 between the first contact portion 110 and the second contact portion 120.

The first contact portion 110 is located at a lengthwise upper portion of the electrically conductive contact pin 10, and the second contact portion 120 is located at a lengthwise lower portion of the electrically conductive contact pin 10.

The first contact portion 110 includes a first lower portion contact portion 111 and a first side portion contact portion 115.

The first lower portion contact portion 111 is brought into contact with a lower portion of a contact object. Thus, the first lower portion contact portion 111 can resist downward displacement of the contact object. Here, the contact object includes the external terminal of the inspection object 20. When the inspection object is a semiconductor package, the contact object may be a spherical external terminal 25 provided in the semiconductor package.

The first side portion contact portion 115 is brought into contact with a side portion of the contact object. Thus, the first side portion contact portion 115 can resist lateral displacement of the contact object. More specifically, the first side portion contact portion 115 is provided outside the first lower portion contact portion 111 and is brought into contact with a side portion of the external terminal 25. With the configuration in which the first lower portion contact portion 111 is brought into contact with the lower portion of the external terminal 25 and the first side portion contact portion 115 is brought into contact with the side portion of the external terminal 25, contact stability with the external terminal 25 can be improved.

The first lower portion contact portion 111 includes a neck portion 112 and a lower surface support portion 113.

When the external terminal 25 of the inspection object 20 has a spherical shape, the lower surface support portion 113 is formed to be curved in the same direction as the curving direction of the spherical external terminal 25 so as to make stable contact with the spherical external terminal 25. The lower surface support portion 113 may have a curvature equal to or greater than that of the spherical external terminal 25. With the configuration of the lower surface support portion 113, the spherical external terminal 25 is brought into contact with the lower surface support portion 113, so that a mark caused by press-contact can be prevented from being generated on the external terminal 25 during contact and overload. Also, the lower surface support portion can serve as a connection part upon contact to enable stable inspection, and the contact area can be increased to facilitate transmission of electrical signals.

The neck portion 112 is provided at a lower portion of the lower surface support portion 113. The neck portion 112 has a first end connected to the boundary portion 114 and a second end connected to the lower surface support portion 113. The neck portion 112 is connected to a center of the lower surface support portion 113 and has a smaller width than a horizontal width of the lower surface support portion 113. When the lower surface support portion 113 and the spherical external terminal 25 are brought into contact with each other, the neck portion 112 is elastically deformed while being bent. Thus, the lower surface support portion 113 is elastically deformed in the left and right directions while maintaining contact with the spherical external terminal 25. When the external terminal 25 of the inspection object 20 and the lower surface support portion 113 are brought into contact with each other, a pressing force is transmitted to the elastic portion 130 through the boundary portion 114.

The boundary portion 114 is provided between the first contact portion and the elastic portion 130 in the length direction and is provided between a pair of connecting portions 300 in the width direction. A first side of the boundary portion 114 is connected to a connecting portion 300 located at a position corresponding the first side, and a second side of the boundary portion 114 is connected to a connecting portion 300 located at a position corresponding to the second side.

The boundary portion 114 has an upper portion connected to the first contact portion 110 and a lower portion connected to the elastic portion 130, and is provided to extend in the width direction. In other words, the boundary portion 114 is provided in a plate shape extending in the width direction, the upper portion of the boundary portion 114 is connected to the first contact portion 110, the lower portion of the boundary portion 114 is connected to the elastic portion 130, and opposite sides of the boundary portion 114 are connected to the respective connecting portions 300. In addition, the first side portion contact portion 115 is connected to the boundary portion 114 and is formed to extend upwardly.

The boundary portion 114 serves to separate a contact region brought into contact with the external terminal 25 of the inspection object 20 and an elastic region in which the elastic portion 130 is elastically deformed into independent spaces. With the configuration of the boundary portion 114 located at an upper portion of the elastic portion 130 and the configuration of the connecting portions 300 located at opposite sides of the elastic portion 130, the contact region brought into contact with the external terminal 25 of the inspection object 20 and the elastic region in which the elastic portion 130 is elastically deformed are separated. With this, foreign substances generated in the contact region during contact can be prevented from being introduced into the elastic region.

A pair of first side portion contact portions 115 are provided outside the first lower portion contact portion 111 and are brought into contact with opposite side portions of the external terminal of the inspection object 20. The first side portion contact portions 115 are formed to protrude longer than a protruding length of the first lower portion contact portion 111 upwardly above the first lower portion contact portion. The external terminal 25 has the lower portion brought into contact with the first lower portion contact portion 111 and the side portions brought into contact with the first side portion contact portions 115. As such, the first lower portion contact portion 111 and the first side portion contact portions 115 surround the spherical external terminal 25 and allow the external terminal 25 to be accommodated therein. As the external terminal 25 is brought into contact with the first lower portion contact portion 111 and the pair of first side portion contact portions 115, contact stability can be improved compared to a conventional point contact method.

The pair of first side portion contact portions 115 are elastically deformed such that the separation distance therebetween increases or decreases. For example, when the first lower portion contact portion 111 is pressed after the first lower portion contact portion 111 is brought into contact with the external terminal 25, the pair of first side portion contact portions 115 may be elastically deformed such that the separation distance therebetween decreases. Alternatively, when the contact object is larger than the separation distance between the pair of first side portion contact portions 115, the pair of first side portion contact portions 115 may be elastically deformed such that the separation distance therebetween increases.

When the external terminal 25 of the inspection object 20 is brought into contact with the first contact portion 110, the external terminal 25 of inspection object 20 may fail to be brought into contact with the first lower portion contact portion 111 due size and position error thereof, but may be at least brought into contact with the first side portion contact portions 115. Since the first side portion contact portions 115 alone can make contact with the external terminal 25 of the inspection object 20, contact stability between the external terminal 25 of the inspection object 20 and the first contact portion 110 can be secured even in a situation where a downward force for pressing the inspection object 20 is small. In the case of a conventional silicon rubber-type electrically conductive contact pin in which conductive microballs are placed inside a silicon rubber made of a rubber material, an inspection object has to be pressed with a sufficiently large stroke in order to form connection between the microballs. Depending on the number of electrically conductive contact pins, a downward force of several to several tens of tons is required. On the contrary, in the case of the electrically conductive contact pin 10 according to the first embodiment of the present disclosure, by providing the first side portion contact portions 115 that are brought into contact with a side surface of the external terminal 25 of the inspection object 20, it is possible to secure contact stability between the external terminal 25 of the inspection object 20 and the first contact portion 110 even with a relatively small downward force.

Each of the first side portion contact portions 115 includes a guide portion 117 inclined outwardly. When the external terminal 25 of the inspection object 20 is seated on the first lower portion contact portion 111, the external terminal 25 of the inspection object 20 may be seated in a slightly misaligned direction. In this case, the guide portion 117 guides the external terminal 25 of the inspection object 20 to smoothly enter between the pair of first side portion contact portions 115 even when the external terminal 25 of the inspection object 20 is seated in a slightly misaligned direction. When an inclination angle of the guide portion 117 is less than 20° or greater than 70° with respect to a vertical line in the length direction, the guiding function thereof is degraded. Thus, it is preferable that the inclination angle of the guide portion 117 ranges from 20° to 70°.

Each of the first side portion contact portions 115 may be formed to extend from the connecting portion 300 or from the boundary portion 114. Each of the first side portion contact portions 115 includes a first extension portion 115a and a second extension portion 115b. The second extension portion 115b extends from the first extension portion 115a in the length direction. The first extension portion 115a has a first end connected to the boundary portion 114 or the connecting portion 300 and a second end connected to the second extension portion 115b. The first extension portion 115a may be formed vertically in the length direction of the electrically conductive contact pin 10 or inclined outwardly at a predetermined angle. The second extension portion 115b extends from the first extension portion 115a and is inclined outwardly at a predetermined angle with respect to the first extension portion 115a. An angle formed by the second extension portion 115b with the vertical line in the length direction is greater than an angle formed by the first extension portion 11a with the vertical line. Here, the second extension portion 115b may constitute the guide portion 117 described above. In addition, the first extension portion 11a may further include a protrusion protruding in the width direction (not illustrated, e.g., an inner protrusion 118 according to a fourth embodiment).

The elastic portion 130 is provided between the boundary portion 114 and the second contact portion 120 in the length direction and is elastically deformed. An uppermost end of the elastic portion 130 is connected to the boundary portion 114, and a lowermost end of the elastic portion 130 is connected to the second contact portion 120.

The elastic portion 130 is formed by alternately connecting a plurality of straight portions 135 and a plurality of curved portions 137. Each of the straight portions 135 connects the curved portions 137 adjacent in the left and right directions, and each of the curved portions 137 connects the straight portions 135 adjacent in the upper and lower directions. The curved portions 137 have an arc shape.

The straight portions 135 are disposed at a central portion of the elastic portion 130, and the curved portions 137 are disposed at outer peripheral portions of each of the elastic portion 130. The straight portions 135 are provided parallel to the width direction so that the curved portions 137 can be more easily deformed by contact pressure. With this, the elastic portion 139 has an appropriate contact pressure.

The elastic portion 130 connected to the boundary portion 114 may be a curved portion 137 of the elastic portion 130, and the elastic portion 130 connected to the second contact portion 120 may be a straight portion 135 of the elastic portion 130. The straight portion 135 at the lowermost end of the elastic portion 130 has a first end serving as a free end and a second end connected to a curved portions 137 so that the second contact portion 120 is operated while performing a scrubbing function.

A flat portion 138 is provided at each of upper and lower portions of each of the curved portions 137. Each of the flat portions 138 has a flat surface shape. The flat portions 138 adjacent in the upper and lower directions are brought into surface contact with each other when the elastic portion 130 is deformed. During inspection, as the elastic portion 130 is compressed, the flat portions 138 adjacent in the upper and lower directions are brought into surface contact with each other. With this, electrical signal transmission can be quickly and stably performed through the curved portions 137 provided at the outer peripheral portions of the elastic portion 130.

Each of the curved portions 137 is connected to two straight portions 135. The two straight portions 135 are located within a range that does not exceed the distance between opposite sides of each of the curved portions 137. One straight portion 135 is connected to a first side of each of the curved portions 137 bent downwardly from the upper portion thereof, and another straight portion 130a is connected to a second side of each of the curved portions 137 bent upwardly from the lower portion thereof. Thus, the distance between the two straight portions 135 connected to one curved portion 137 does not exceed the distance between opposite sides of the one curved portion 137. With this, it is possible to provide more curved portions 137 and straight portions 135 within the same length range of the elastic portion 130, so that the elastic portion 130 can have sufficient elasticity. As a result, it is possible to shorten the length of the elastic portion 130.

Meanwhile, the distance between the curved portions 137 adjacent in the upper and lower directions is shorter than that between the straight portions 135 adjacent in the upper and lower directions. With this, when the elastic portion 130 is compressed, the curved portions 137 adjacent in the upper and lower directions are brought into contact with each other first to form a current path through the curved portions 137, and then when an additional overdrive is applied, the elastic portion 130 is further deformed through the straight portions 135 adjacent in the upper and lower directions.

The second contact portion 120 is provided at the lowermost end of the elastic portion 130 and is formed such that a horizontal width thereof decreases toward an end thereof. In addition, the second contact portion 120 may be provided in plural as in a fifth embodiment.

The fixing portion 200 is provided at a widthwise outermost side of the electrically conductive contact pin 10 and serves to fix the electrically conductive assembly 10 to the housing plate 30. After the elastically conductive contact pin 10 is installed in the housing plate 30, the fixing portion 200 remains fixed to the housing plate 30.

The fixing portion 200 includes a protrusion 210 protruding outwardly in the width direction. The protrusion 210 is provided on a wall surface of the fixing portion 200. The protrusion 210 includes a fixing protrusion 211 for fixing the fixing portion 200 to the housing plate and a friction reducing protrusion 213 for reducing friction with an inner wall surface of the housing plate 30.

At least one fixing protrusion 211 is formed and protrudes outwardly longer than a protruding length of the friction reducing protrusion 213.

The friction reducing protrusion 213 is formed to have the same thickness as that of a wall surface constituting the fixing portion 200 and is curved outwardly. In other words, the friction reducing protrusion is convex on an outer wall surface of the fixing portion 200 and is concave on an inner wall surface of the fixing portion 200. With this, when the friction reducing protrusion 213 is brought into contact with the inner wall surface of the housing plate 30, excessive deformation of the fixing portion 200 can be prevented while reducing contact resistance.

The fixing portion 200 includes an extension protrusion 220. The extension protrusion 220 is a part of the fixing portion 200 that extends upwardly and protrudes above the housing plate when the electrically conductive contact pin 10 is installed in the housing plate 30. The extension protrusion 220 may be provided at an upper portion of the fixing protrusion 211 provided at an upper portion of the fixing portion 200. The extension protrusion 220 prevents each of the first side portion contact portions 115 from being excessively deformed by supporting a side surface of the first side portion contact portion 115 when the first side portion contact portion 115 is deformed outwardly in the width direction.

At least a part of the elastic portion 130 protrudes outwardly downwardly below a lower end of the fixing portion 200. In other words, at least the portion of the elastic portion 130 is exposed by further protruding downwardly than the fixing portion 200. In addition, at least a part of the first contact portion 110 protrudes outwardly upwardly above an upper end of the fixing portion 200. In other words, at least the portion of the first contact portion 110 is exposed by further protruding upwardly than the fixing portion 200. With this, when contact objects are brought into contact with the electrically conductive contact pin 10 from above and below the electrically conductive contact pin 10, interference of the contact objects with the fixing portion 200 can be minimized, thereby improving contact stability of the contact objects brought into contact with the electrically conductive contact pin 10 in the length direction.

The connecting portion 300 is provided between the pin portion 100 and the fixing portion 200 in the width direction and connects the pin portion 100 and the fixing portion 200 to each other. The connecting portion 300 extends in the same length direction as that of the fixing portion 200.

The connecting portion 300 is connected to at least a part of the pin portion 100 and is connected to the lower end of the fixing portion 200. Preferably, the connecting portion 300 has a first end connected to the boundary portion 114 and a second end connected to the lower end of the fixing portion 200, and the connecting portion 300 and the fixing portion 200 are connected to each other by a “U” (the alphabet U)-shaped bent portion 400. In other words, the fixing portion 200 and the connecting portion 300 are spaced apart from each other in parallel, and the lower end of the fixing portion 200 and the lower end of the connecting portion 300 are connected to each other by the bent portion 400. With the configuration in which the connecting portion 300 is provided inside the fixing portion 200 to be spaced apart from the fixing portion 200 and the fixing portion 200 and the connecting portion 300 are connected to each other by the “U” (the alphabet U)-shaped bent portion 400, not only the pin portion 100 is elastically allowed to be displaced in the width direction, but also the pin portion 100 is elastically allowed to be displaced in the length direction.

The lower end of the fixing portion 200 and the lower end of the connecting portion 300 are connected to each other by the bent portion 400 at a position lower than the boundary portion 114 in the length direction, so that the boundary portion 114 is relatively displaceable in the width direction with respect to the fixing portion 200. When contact is made with the external terminal of the inspection object 20 at a position above the boundary portion 114, the boundary portion 114 is brought into contact with the external terminal 25 while being relatively displaced in the width direction with respect to the fixing portion 200. With this, it is possible to improve contact stability even when the external terminal 25 approaches from a misaligned position.

Meanwhile, during inspection, a lower end of the bent portion 400 is brought into contact with an upper surface of a circuit board 40 to serve as a stopper, thereby preventing the elastic portion 130 from being excessively compressed.

As the widthwise deformation of the electrically conductive contact pin 10 is elastically allowed, it is possible to more easily install and replace the electrically conductive contact pin 10 in the housing plate 30.

More specifically, the connecting portion 300 is relatively movable with respect to the fixing portion 200 so that a separation space between the fixing portion 200 and the connecting portion 300 is changed. An inner width of a hole formed in the housing plate 30 is configured to be smaller than the width of the electrically conductive contact pin 10 before insertion. When inserting the electrically conductive contact pin 10 into the hole provided in the housing plate 30, it is possible to narrow the width of the electrically conductive contact pin 10 by compressing a lower end of the electrically conductive contact pin 10 in the width direction. Thus, the electrically conductive contact pin can be easily inserted into the hole provided in the housing plate 30. After insertion, the fixing portion 200 is brought into close contact with an inner wall of the hole provided in the housing plate 30 by an elastic restoring force between the fixing portion 200 and the connecting portion 300. As such, it is possible to easily install the electrically conductive contact pin 10 in the housing plate 30 through the elastic coupling between the fixing portion 200 and the connecting portion 300.

Also, it is possible to easily remove the electrically conductive contact pin 10 already installed in the housing plate 30. Since the electrically conductive contact pin 10 is elastically deformed in the width direction, it can be easily removed from the housing plate 30 by compressing the fixing portion 200 in the width direction.

As the widthwise displacement of the pin portion 100 is elastically allowed, more stable contact with the external terminal 25 is possible. Since the connecting portion 300 is relatively displaceable in the width direction with respect to the fixing portion 200 and the pin portion 100 is integrally formed with the connecting portion 300, the pin portion 100 can be elastically tilted in the left and right directions in a predetermined angle range. Even when the external terminal 25 is brought into contact with the first contact portion 110 at a misaligned position (due to a manufacturing process or a transfer error, etc.), the first contact portion 110 can be brought into contact with the external terminal 25 while being tilted by a pressing force of the external terminal at the misaligned position. With this, stable connection is possible even with the external terminal 25 having a position error.

The boundary portion 114 is provided to be elastically movable in the width direction with respect to the fixing portion 200. The first side portion contact portions 115 connected to the boundary portion 114 are provided to be elastically movable in the width direction. The bent portion 400 connecting the fixing portion 200 and the connecting portion 300 is provided to be elastically movable in the width direction. The fixing portion 200 is provided to be elastically movable in the width direction with respect to the bent portion 400.

The second contact portion 120 is electrically connected to a terminal 45 of the circuit board 40. Since the second contact portion 120 is connected to the elastic portion 130 at a lower portion of the elastic portion 130, the second contact portion 120 is elastically connected to the terminal 45 of the circuit board 40.

Meanwhile, the housing plate 30 may be made of an anodic aluminum oxide film. In other words, the housing plate 30 may be made of an anodic aluminum oxide film formed by anodizing a base metal and then removing the base metal. The anodic aluminum oxide film means a film formed by anodizing a metal as a base material, and pores mean holes formed in the process of forming the anodic aluminum oxide film by anodizing the metal. As an embodiment, when the base metal is aluminum (Al) or an aluminum alloy, the anodization of the base metal forms the anodic aluminum oxide film consisting of anodized aluminum (Al₂O₃) on a surface of the base metal. However, the base metal is not limited thereto, and includes Ta, Nb, Ti, Zr, Hf, Zn, W, Sb, or an alloy of these metals. When the housing plate 30 is made of the anodic aluminum oxide film, it is possible to prevent the housing plate 30 from being deformed by surrounding heat and thus prevent the position of the elastically conductive contact pin 10 from being misaligned. In addition, it is possible to form holes in the housing plate 30 by etching the anodic aluminum oxide film, so that it is possible to precisely process the holes according to the outer shape of the electrically conductive contact pin 10.

An electrically conductive contact pin 10 according to an embodiment of the present disclosure is provided as a single body in which thin plates are integrally connected to each other.

The electrically conductive contact pin 10 is provided as a single body, and includes: a pair of fixing portions 200 formed in the form of a plate extending in the length direction; a pair of connecting portions 300 each of which is connected through a connection portion to a lower end of each of the fixing portions 200 and formed in the form of a plate extending in the length direction; a boundary portion 114 connected to the connecting portions 300 and formed in the form of a plate extending in the width direction; a first contact portion 110 connected to the boundary portion 114 or the connecting portions 300 and formed in the form of a plate; an elastic portion 130 connected to the boundary portion 114 or the connecting portions 300 and formed in the form of a plate; and a second contact portion 120 connected to the elastic portion 130 and formed in the form of a plate.

More specifically, the pair of fixing portions 200 are formed in the form of a plate extending in the length direction. In addition, the connecting portions 300 respectively connected to lower ends of the fixing portions 200 are formed in the form a plate extending in the length direction. In addition, the boundary portion 114 connecting the connecting portions 300 to each other is formed in the form a plate extending in the width direction from upper ends of the connecting portions 300. In addition, the pair of connecting portions 300 and the boundary portion 114 form a “Π”-shaped half-closed space with an open lower portion. In addition, in the half-closed space formed by the pair of connecting portions 300 and the boundary portion 114, the elastic portion 130 is formed in the form of a plate with a curved portion and is integrally connected to at least one of the pair of connecting portions 300 and the boundary portion 114. The elastic portion 130 is formed in the form of a plate with a curved portion 137 and a straight portion 135. In addition, the first contact portion 110 is formed in the form of a plate and is integrated with the boundary portion 114 or the connecting portions 300, and the second contact portion 120 is formed in the form of a plate and is integrated with the elastic portion 130. The second contact portion 120 may be in the form of a plate thicker than the plate constituting the elastic portion 130 or may be in the form of a plate having the same thickness as that of the plate constituting the elastic portion 130 as in a third embodiment.

As described above, the electrically conductive contact pin 10 is provided as a single body in which the plates are integrally connected to each other.

The electrically conductive contact pin 10 has an overall length L in the length direction, an overall thickness H in the thickness direction perpendicular to the length direction, and an overall width W in the width direction perpendicular to the length direction.

The plates constituting the electrically conductive contact pin 10 have a width. Here, the width means a distance between a first surface of the plates and a second surface thereof facing the first surface. The plates constituting the electrically conductive contact pin 10 have a minimum width corresponding to the smallest width and a maximum width corresponding to the largest width.

An actual width t of the plates may be an average value of the widths of all the plates, or a median value of the widths of all the plates, or an average value or a median value of the widths of the plates corresponding to at least a part of the configurations constituting the electrically conductive contact pin 10, or an average value or a median value of the width of at least one of the plates corresponding to the fixing portions 200, the connecting portions 300, the boundary portion 114, and the elastic portion 130, or a value of the width obtained when the plates are continuous with the same width by equal to or larger than 10 μm.

In order to effectively cope with the test of high-frequency characteristics of the inspection object 20, the overall length L of the electrically conductive contact pin 10 has to be short. Thus, the length of the elastic portion 130 has to also be shortened. However, when the length of the elastic portion 130 is shortened, a problem occurs in that contact pressure increases. In order to shorten the length of the elastic portion 130 without increasing the contact pressure, the actual width t of the plate constituting the elastic portion 130 has to be small. However, when the actual width t of the plate constituting the elastic portion 130 is shortened, a problem occurs in that the elastic portion 130 tends to be damaged. In order to shorten the length of the elastic portion 130 without increasing the contact pressure and prevent damage to the elastic portion 130, the overall thickness H of the plate constituting the elastic portion 130 has to be large.

The electrically conductive contact pin 10 according to the embodiment of the present disclosure is formed such that the actual width t of the plates is small while the overall thickness H of the plates is large. In other words, the overall thickness H is configured to be large compared to the actual width t of the plates. Preferably, the actual width t of the plates constituting the electrically conductive contact pin 10 is in the range of 5 μm to 15 μm, the overall thickness H is in the range of 70 μm to 200 μm, and the actual width t of the plates and the overall thickness H have a ratio in the range of 1:5 to 1:30. For example, the actual width t of the plates may be substantially 10 μm, and the overall thickness H may be 100 μm, so that the actual width t of the plates and the overall thickness H may have a ratio of 1:10.

With this, it is possible to shorten the length of the elastic portion 130 while preventing damage to the elastic portion 130, and it is possible for the elastic portion 130 to have an appropriate contact pressure even when the length thereof is shortened. Furthermore, as it is possible to increase the overall thickness H compared to the actual width t of the plate constituting the elastic portion 130, the resistance to moments acting in the front and rear directions of the elastic portion 130 is increased, resulting in improved contact stability.

As it is possible to shorten the length of the elastic portion 130, the overall thickness H and the overall length L of the electrically conductive contact pin 10 have a ratio in the range of 1:3 to 1:9. Preferably, the overall length L of the electrically conductive contact pin 10 is in the range of 300 μm to 2 mm, and more preferably 450 μm to 600 μm. As such, as it is possible to shorten the overall length L of the electrically conductive contact pin 10, it is possible to effectively cope with high-frequency characteristics. Also, the elastic recovery time of the elastic portion 130 can be shortened, thereby shortening the test time.

In addition, as the actual width t of the plates constituting the electrically conductive contact pin 10 is configured to be smaller than the overall thickness H thereof, bending resistance in the front and rear directions can be improved.

The elastic portion 130 is elastically deformed by receiving a pressing force, and includes a plurality of curved portions 137 that are brought into contact with each other to form a current path. Thus, it is preferable that the curved portions 137 adjacent in the upper and lower directions are entirely brought into contact with each other by the pressing force. To this end, the plate constituting the elastic portion 130 may be formed such that the actual width t thereof gradually increases or decreases. Preferably, the plate constituting the elastic portion 130 is formed such that the actual width t thereof gradually decreases.

The overall thickness H and the overall width W of the electrically conductive contact pin have a ratio in the range of 1:1 to 1:5. Preferably, the overall thickness H of the electrically conductive contact pin 10 is in the range of 70 μm to 200 μm, and the overall width W of the electrically conductive contact pin 10 is in the range of 100 μm to 500 μm. More preferably, the overall width W of the electrically conductive contact pin 10 is in the range of 150 μm to 400 μm. By shortening the overall width W of the electrically conductive contact pin 10 as described above, it is possible to implement a narrower pitch.

Meanwhile, the overall thickness H and the overall width W of the electrically conductive contact pin 10 may be configured to be substantially the same. Thus, it is not necessary to join a plurality of separately manufactured electrically conductive contact pins 10 in the thickness direction so that the overall thickness H and the overall width W become substantially the same. In addition, as it is possible to make the overall thickness H and the overall width W of the electrically conductive contact pin 10 substantially the same, the resistance to moments acting in the front and rear directions of the electrically conductive contact pin 10 is increased, resulting in improved contact stability. Furthermore, with the configuration in which the overall thickness H of the electrically conductive contact pin 10 is equal to or larger than 70 μm and the ratio of the overall thickness H to the overall width W thereof is in the range of 1:1 to 1:5, overall durability and deformation stability of the electrically conductive contact pin 10 can be improved and thereby contact stability with the external terminal 25 can be improved. In addition, as the overall thickness H of the electrically conductive contact pin 10 is configured to be equal to or larger than 70 μm, it is possible to improve current carrying capacity.

When the electrically conductive contact pin 10 is manufactured using a conventional photoresist mold, the overall thickness H is smaller than the overall width W. For example, in the case of a conventional electrically conductive contact pin 10, the overall thickness H may be less than 70 μm and the overall thickness H and the overall width W may have a ratio in the range of 1:2 to 1:10. Thus, the resistance to moments that deform the electrically conductive contact pin 10 in the front and rear directions by contact pressure is weak. In order to prevent problems occurring due to excessive deformation of the elastic portion 130 on front and rear surfaces of the electrically conductive contact pin 10, it should be considered to additionally form a housing on the front and rear surfaces of the electrically conductive contact pin 10. However, according to the embodiment of the present disclosure, an additional housing is not necessary.

Hereinafter, a description will be given of a process for installing the electrically conductive contact pin 10 according to the first embodiment of the present disclosure in the housing plate 30.

First, the housing plate 30 having a plurality of holes is provided. The inner width of each of the holes formed in the housing plate 30 is configured to be smaller than the overall width T of the electrically conductive contact pin 10. More specifically, the inner width of each of the holes provided in the housing plate 30 is configured to be smaller than the width between the pair of fixing portions 200.

With the configuration of the connecting portions 300 each of which is connected to a part of the pin portion 100 and connected to a part of each of the pair of fixing portions 200, the pair of fixing portions 200 are elastically deformable in the width direction. The fixing portions 200 at a lower end of the electrically conductive contact pin 10 are compressed in the width direction so that the width thereof becomes smaller than the inner width of each of the holes provided in the housing plate 30, after which the electrically conductive contact pin 10 is inserted into each of the holes provided in the housing plate 30.

Then, the electrically conductive contact pin 10 is forcibly pushed into the hole provided in the housing plate 30 by pressing the electrically conductive contact pin 10 downwardly. The electrically conductive contact pin 10 is compressed in the width direction and moved to a lower portion of the hole provided in the housing plate 30. In this case, the fixing portions 200 are moved downwardly with a small frictional force by friction reducing protrusions 213 provided on outer wall surfaces of the fixing portions 200 while being in close contact with the inner wall of the hole provided in the housing plate 30 by an elastic restoring force.

As the fixing protrusion 211 is supported on an upper surface of the housing plate 30, the electrically conductive contact pin 10 is fixedly installed in the housing plate 30, and installation of the electrically conductive contact pin 10 in the housing plate 30 is completed.

Hereinafter, an operation process of the electrically conductive contact pin 10 according to the first embodiment of the present disclosure will be described with reference to FIG. 4.

While the fixing portions 200 of the electrically conductive contact pin 10 remain fixed to the housing plate 30, the pin portion 100 can be elastically displaced in the length and width directions with respect to the fixing portions 200.

When the semiconductor package 20 or the housing plate 30 is moved relatively close to each other, the external terminal 25 is guided into the space formed by the first lower portion contact portion 111 and the first side portion contact portions 115. Thereafter, the lower portion of the external terminal 25 of the inspection object 20 is brought into contact with the upper surface of the first lower portion contact portion 111, and the side portions of the external terminal 25 are brought into contact with the side surfaces of the first side portion contact portions 115.

Even when the inspection object 20 is moved downwardly from a position misaligned with the first lower portion contact portion 111, it is possible to guide the external terminal into the space formed by the first lower portion contact portion 111 and the first side portion contact portions 115. When the external terminal 25 moved downwardly from the misaligned position is brought into contact with guide portions 117 of the first side portion contact portions 115, the pin portion 100 is elastically displaced or tilted toward the misaligned position. With this, the external terminal 25 can be received into the space formed by the first lower portion contact portion 111 and the first side portion contact portions 115. The external terminal 25 received into the space formed by the first lower portion contact portion 111 and the first side portion contact portions 115 is brought into contact with the upper surface of the first lower portion contact portion 111, the lower surface support portion 113 of the first lower portion contact portion 111 is brought into contact with the external terminal 25 while being tilted by a contact pressing force of the external terminal 25. With this, contact stability can be improved.

In addition, as the elastic portion 130 is compressed in the length direction, the curved portions 137 adjacent in the upper and lower directions are brought into contact with each other. More specifically, the flat portions 138 provided at the upper and lower portions of the curved portions 137 are brought into contact with the flat portions 138 adjacent thereto in the upper and lower directions. When the curved portions 137 are brought into contact with each other, an electrical signal is transmitted through the curved portions 137 in contact with each other, thereby enabling faster inspection.

### Second Embodiment

Next, the second embodiment according to the present disclosure will be described. However, the embodiments described below will be mainly described in terms of characteristic elements in comparison with the first embodiment, and descriptions of the same or similar elements to the first embodiment will be omitted.

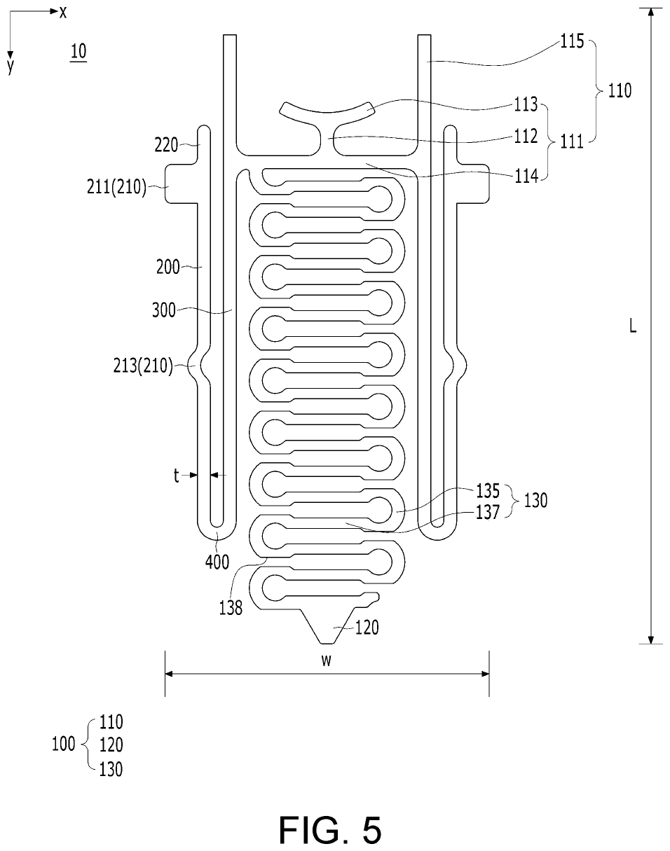

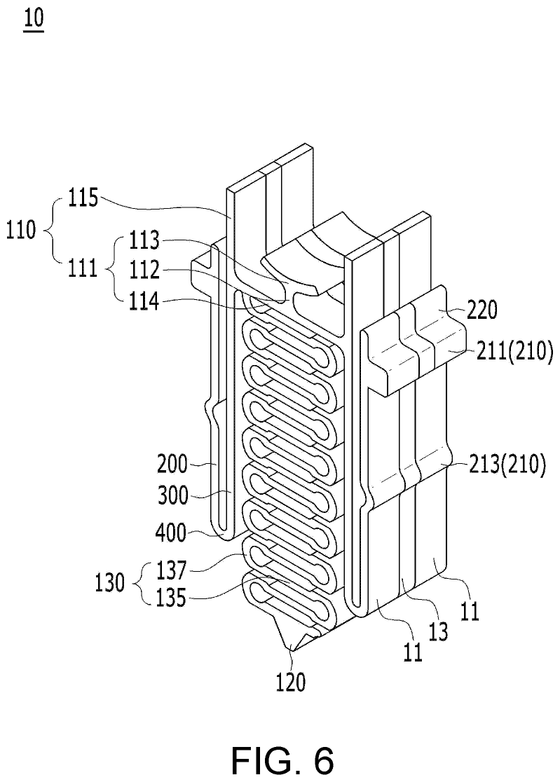

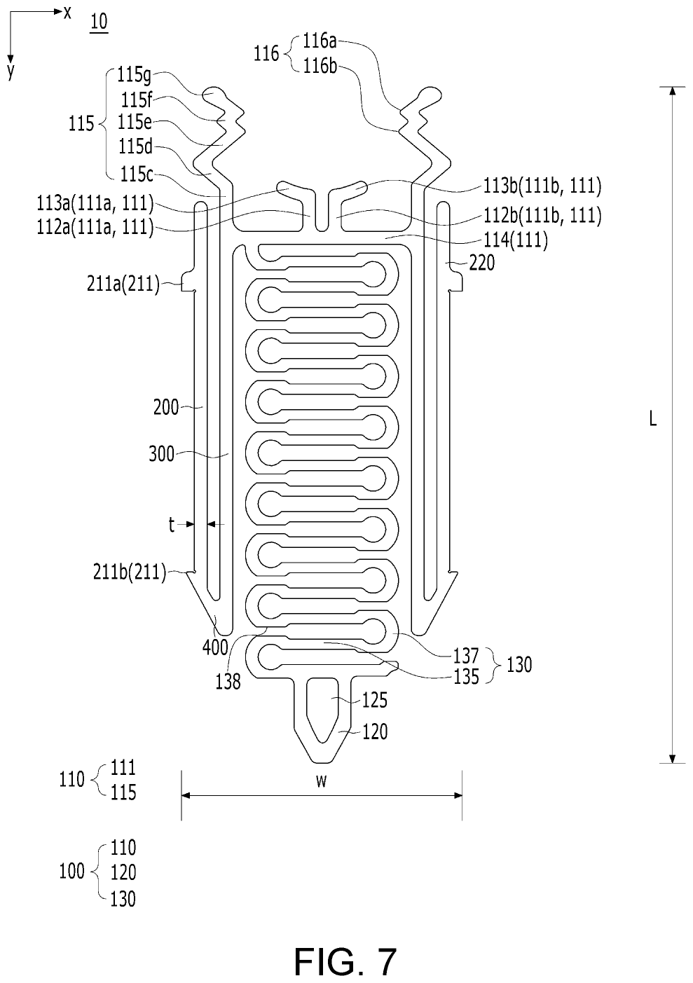

Hereinafter, an electrically conductive contact pin 10 according to the second embodiment of the present disclosure will be described with reference to FIGS. 5 and 6. FIG. 6 is a plan view illustrating the electrically conductive contact pin 10 according to the second embodiment of the present disclosure. FIG. 7 is a perspective view illustrating the electrically conductive contact pin according to the second embodiment of the present disclosure.

The electrically conductive contact pin 10 according to the second embodiment of the present disclosure remains the same as the electrically conductive contact pin 10 according to the first embodiment, except for the configuration of a pin portion 100.

In the electrically conductive contact pin 10 according to the second embodiment of the present disclosure, a first side portion contact portion 115 is formed to extend on the length axis of a connecting portion 300. A lower portion of the first side portion contact portion 115 is connected to an upper portion of the connecting portion 300 and a side portion of a boundary portion 114 at a point where they intersect with each other. In addition, the first side portion contact portion 115 does not include a separate guide portion 117.

### Third Embodiment

Next, the third embodiment according to the present disclosure will be described. However, the embodiments described below will be mainly described in terms of characteristic elements in comparison with the first embodiment, and descriptions of the same or similar elements to the first embodiment will be omitted.

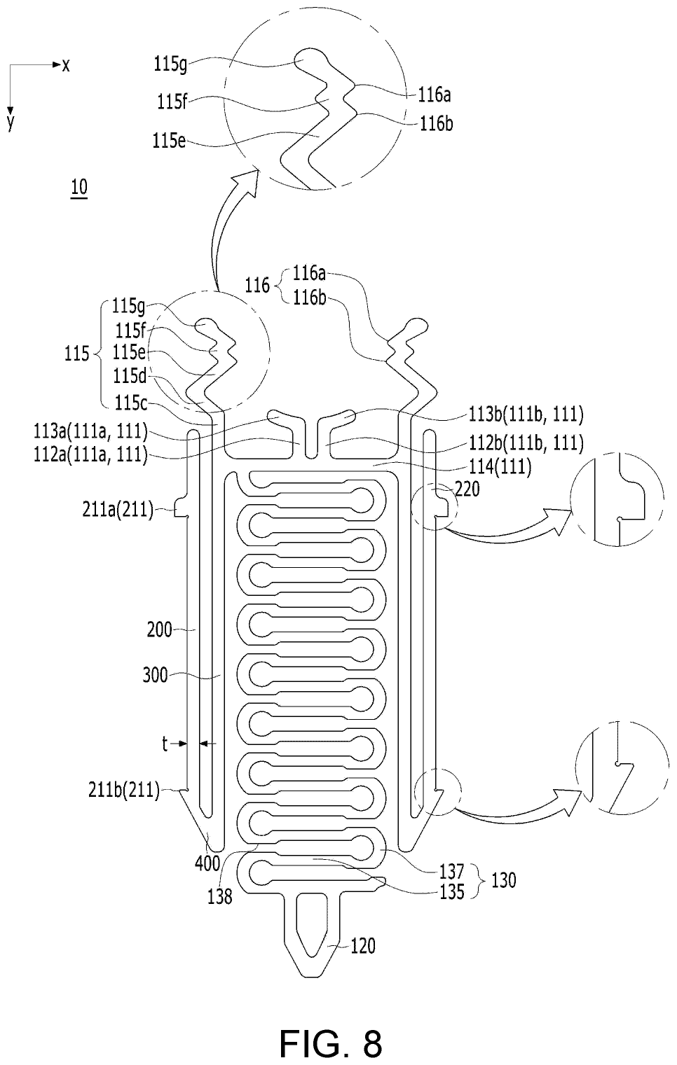

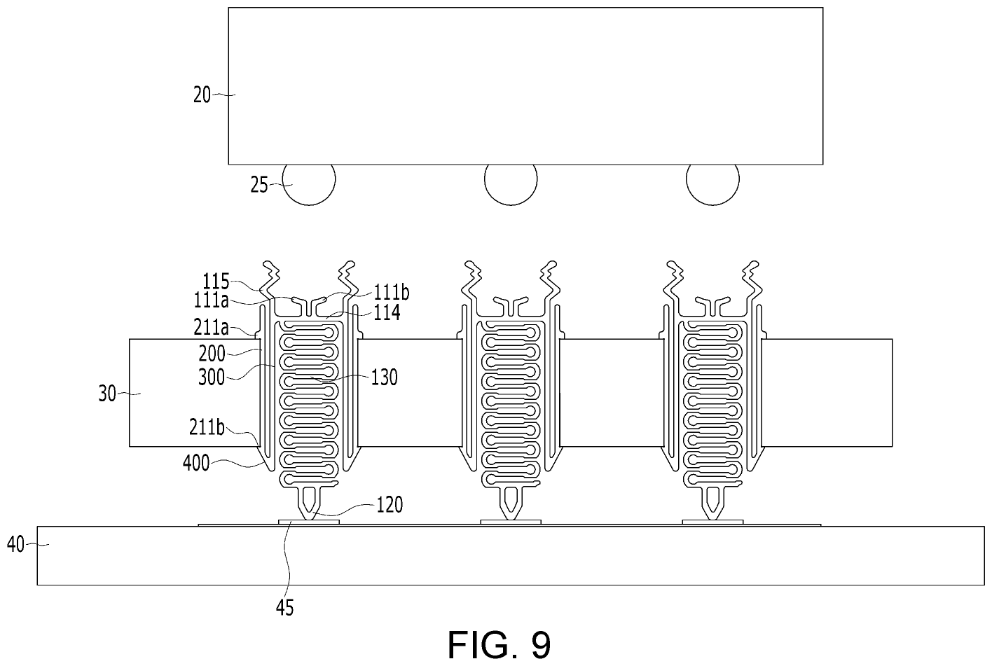

Hereinafter, an electrically conductive contact pin 10 according to the third embodiment of the present disclosure will be described with reference to FIGS. 7 to 9. FIG. 7 is a plan view illustrating the electrically conductive contact pin 10 according to the third embodiment of the present disclosure. FIG. 8 is a partially enlarged view illustrating the electrically conductive contact pin 10 according to the third embodiment of the present disclosure. FIG. 9 is a view illustrating a state before electrically conductive contact pins 10 according to the third embodiment of the present are inspected in a state of being installed in a housing plate 30.

The electrically conductive contact pin 10 according to the third embodiment of the present disclosure includes a pin portion 100, a fixing portion 200, and a connecting portion 300.

The pin portion100 includes a first contact portion 110, a second contact portion 120, and an elastic portion130 between the first contact portion 110 and the second contact portion 120. The first contact portion 110 is located at a lengthwise upper portion of the electrically conductive contact pin 10, and the second contact portion 120 is located at a lengthwise lower portion of the electrically conductive contact pin 10.

The first contact portion 110 includes a first lower portion contact portion 111 and a first side portion contact portion 115.

The first lower portion contact portion 111 includes a first-first lower portion contact portion 111a and a first-second lower portion contact portion 111b. The first-first lower portion contact portion 111a and the first-second lower portion contact portion 111b are symmetrically spaced apart from each other in the width direction with respect to the lengthwise central axis of the pin portion 100.

The first-first lower portion contact portion 111a includes a first lower surface support portion 113a brought into contact with a part of a lower portion of an external terminal 25 of an inspection object 20 and extending to the left in the width direction and upwardly in the length direction. The first-second lower portion contact portion 111b includes a second lower surface support portion 113b brought into contact with a part of the lower portion of the external terminal of the inspection object 20 and extending to the right in the width direction and upwardly in the length direction.

A first neck portion 112a is provided at a lower portion of the first lower surface support portion 113a. The first neck portion 112a has a first end connected to a boundary portion 114 and a second end connected to the first lower surface support portion 113a. A second neck portion 112b is provided at a lower portion of the second lower surface support portion 113b. The second neck portion 112b has a first end connected to the boundary portion 114 and a second end connected to the second lower surface support portion 113b.

When the external terminal 25 of the inspection object 20 is brought into contact with the first-first lower portion contact portion 111a and the first-second lower portion contact portion 111b, the first lower surface support portion 113a and the second lower surface support portion 113b support the lower portion of the external terminal 25 while being elastically deformed in directions away from each other. In addition, even when the external terminal 25 of the inspection object 20 fails to be seated at a correct position and is eccentrically seated, the first lower surface support portion 113a or the second lower surface support portion113b may be brought into contact with the lower portion of the external terminal 25 of the inspection object 20. As such, as the first lower portion contact portion 111 is composed of the first-first lower portion contact portion 111a and the first-second lower portion contact portion 111b spaced apart from each other, contact stability with the external terminal 25 of the inspection object 20 can be further improved.

In addition, a separation space is provided between the first-first lower portion contact portion 111a and the first-second lower portion contact portion 111b. More specifically, a separation space exists between the first neck portion 112a of the first lower portion contact portion 111a and the second neck portion 112b of the second lower portion contact portion 111b. The separation space provided between the first neck portion 112a and the second neck portion 112b is formed long in the length direction, and the boundary portion 114 is located below the separation space. Foreign substances falling off from the external terminal 25 of the inspection object 20 are guided by the first lower surface support portion 113a of the first lower portion contact portion 111a and the second lower surface support portion 113b of the second lower portion contact portion 111b to be introduced into the separation space between the first neck portion 112a and the second neck portion 112b. With this, it is possible to minimize foreign substances remaining on the first lower surface support portion 113a of the first lower portion contact portion 111a and the second lower surface support portion 113b of the second lower portion contact portion 111b, thereby improving contact stability.

A pair of first side portion contact portions 115 are provided outside the first lower portion contact portion 111 and are brought into contact with side portions of the external terminal 25 of the inspection object 20. The first side portion contact portions 115 are formed to protrude longer than a protruding length of the first lower portion contact portion 111 upwardly above the first lower portion contact portion. The spherical external terminal 25 has the lower portion brought into contact with the first lower portion contact portion 111 and the side portions brought into contact with the first side portion contact portions 115. As the spherical external terminal 25 is brought into contact with the first lower portion contact portion 111 and the pair of first side portion contact portions 115, contact stability can be improved compared to a conventional point contact method.

The pair of first side portion contact portions 115 are elastically deformed such that the separation distance therebetween increases or decreases. For example, when the first lower portion contact portion 111 is pressed after the first lower portion contact portion 111 is brought into contact with the spherical external terminal 25, the pair of first side portion contact portions 115 may be elastically deformed such that the separation distance therebetween decreases. Alternatively, when the width of the external terminal 25 of the inspection object 20 is larger than the separation distance between the pair of first side portion contact portions 115, the pair of first side portion contact portions 115 may be elastically deformed such that the separation distance therebetween increases.

Each of the first side portion contact portions 115 includes a side surface support portion 115f brought into contact with a side surface of the external terminal 25 of the inspection object 20. The side surface support portion 115f has a protruding tip 116 to improve contact stability. The protruding tip 116 protrudes inwardly in the width direction, and may be provided in plural. At least two protruding tips 116 may be provided, and may include, for example, an upper protruding tip 116a and a lower protruding tip 116b. The upper protruding tip 116a is provided at an upper portion of the lower protruding tip 116b. The upper protruding tip 116a and the lower protruding tip 116b may have vertical tangent lines at different positions. The lower protruding tip 116b may protrude further inwardly in the width direction than the upper protruding tip 116a. When the first lower portion contact portion 111 receives a downward pressure caused by overdrive when brought into contact with the external terminal 25 of the inspection object 20, the fixing portion 200 is brought into contact with each of the first side portion contact portions 115, causing the first side portion contact portion 115 to be displaced toward the external terminal 25 of the inspection object 20. In this case, the upper protruding tip 116a and the lower protruding tip 116b are brought into contact with the side surface of the external terminal 25 of the inspection object 20, thereby improving contact stability.

Each of the first side portion contact portions 115 includes a plurality of extension portions. For example, the first side portion contact portion 115 includes a first extension portion 115c connected to the boundary portion 114, a second extension portion 115d extending from the first extension portion 115c and extending outwardly in the width direction, a third extension portion 111e extending from the second extension portion 115d and extending inwardly in the width direction, the side surface support portion 115f extending from the third extension portion 111e, and a fourth extension portion 115g extending from the side surface support portion 115f and extending outwardly in the width direction. However, the number of the first to fourth extension portions 115c, 115d, 115e, and 115g is not limited thereto. With the configuration of the extension portions that are bent in opposite directions, the side surface support portion 115f can elastically support the side surface of the external terminal 25 of the inspection object 20. In addition, with the configuration of the extension portion (fourth extension portion 115g) located at an upper portion of the side surface support portion 115f, when the external terminal 25 of the inspection object 20 is seated on the first lower portion contact portion 111, the extension portion serves to guide the external terminal 25 of the inspection object 20 to smoothly enter between the pair of first side portion contact portions 115 even when the external terminal 25 of the inspection object 20 is seated in a slightly misaligned direction.

In addition, when the pin portion 100 is displaced downwardly, the second extension portion 115d is brought into contact with an upper end of the fixing portion 200 to displace the side surface support portion 115f inwardly in the width direction, thereby improving contact stability with the external terminal 25.

Each of the first side portion contact portions 115 may be formed to extend from the connecting portion 300 or from the boundary portion 114.

The second contact portion 120 has the same width as the elastic portion 130, and includes a free space portion 125 therein. The free space portion 125 is formed as an empty space surrounded by the second contact portion 120 and a straight portion 135 of the elastic portion 130. With the configuration of the free space portion 125, the second contact portion 120 can have the same width as the elastic portion 130.

The fixing portion 200 is provided at a widthwise outermost side of the electrically conductive contact pin 10 and serves to fix the electrically conductive assembly 10 to the housing plate 30. After the elastically conductive contact pin 10 is installed in the housing plate 30, the fixing portion 200 remains fixed to the housing plate 30.

The fixing portion 200 includes a protrusion 210 protruding outwardly in the width direction. The protrusion 210 is provided on a wall surface of the fixing portion 200. The protrusion 210 includes a fixing protrusion 211 for fixing the fixing portion 200 to the housing plate 30.

The fixing protrusion 211 includes an upper fixing protrusion 211a and a lower fixing protrusion 211b. With the configuration of the upper fixing protrusion 211a and the lower fixing protrusion 211b, the fixing portion 200 is fixedly installed in the housing plate 30.

The housing plate 30 is located between the upper fixing protrusion 211a and the lower fixing protrusion 211b. The upper fixing protrusion 211a and the lower fixing protrusion 211b are provided as stepped locking protrusions, so that after the fixing portion 200 is inserted into a hole formed in the housing plate 30, the housing plate 30 is caught by the upper fixing protrusion 211a and the lower fixing protrusion 211b to prevent the fixing portion 200 from being separated upwardly.

The upper fixing protrusion 211a is inclined downwardly outwardly in the width direction in order to prevent the fixing portion 200 from moving after the fixing portion 200 is inserted into the hole formed in the housing plate 30.

The fixing portion 200 and the connecting portion 300 are spaced apart from each other in parallel, and a lower end of the fixing portion 200 and a lower end of the connecting portion 300 are connected to each other by a bent portion 400. The bent portion 400 has an outer surface inclined inwardly in the width direction. With this, the electrically conductive contact pin 10 can be more easily inserted into the hole formed in the housing plate 30. When inserting the electrically conductive contact pin 10 into the hole provided in the housing plate 30, as the bent portion 400 having the inclined outer surface is brought into contact with the hole provided in the housing plate 30, the bent portion 400 is compressed inwardly in the width direction and naturally inserted into the hole provided in the housing plate 30. After being inserted, as the electrically conductive contact pin 10 is brought into close contact with an inner wall of the hole provided in the housing plate 30 by an elastic restoring force, the fixing portion 200 is naturally fixed to the housing plate 30 by the upper fixing protrusion 211a and the lower fixing protrusion 211b.

The electrically conductive contact pin 10 is provided as a single body in which thin plates having substantially the same width t are integrally connected to each other. More specifically, a pair of fixing portions 200 extend in the length direction and are formed in the form of a plate. Each of the connecting portions 300 connected through a connection portion at a lower end of each of the fixing portions 200 is formed by extending in the form of a plate in the length direction. The boundary portion 114 extending in the width direction from an upper end of each of the connecting portions 300 and connecting the connecting portions 300 to each other is continuously formed in the form of a plate. In addition, the pair of connecting portions 300 and the boundary portion 114 form a “Π”-shaped half-closed space with an open lower portion. In addition, in the half-closed space formed by the pair of connecting portions 300 and the boundary portion 114, the elastic portion 130 is formed in the form of a plate. The elastic portion 130 is integrally connected to at least one of the pair of connecting portions 300 and the boundary portion 114. In addition, the first contact portion 110 is formed in the form of a plate and is integrated with the boundary portion 114, and the second contact portion 120 is formed in the form of a plate integrated and is integrated with the elastic portion 130.

The fixing portion 200, the connecting portions 300, and the boundary portion 114 are configured as planar plates. The first contact portion 110, the elastic portion 130, and the second contact portion 120 are configured as at least partially curved plates.

As such, the electrically conductive contact pin 10 is provided as a single body in which the plates having substantially the same width are integrally connected to each other.

Since the electrically conductive contact pin 10 is manufactured by stacking a plurality of metal layers through electroplating, plating deviation of the electrically conductive contact pin 10 can be minimized by making the width t of the plates constituting the electrically conductive contact pin 10 substantially the same. With this, electrical or physical characteristics of the electrically conductive contact pin 10 can be made uniform.

Hereinafter, a description will be given of a process for installing the electrically conductive contact pin 10 according to the third embodiment of the present disclosure in the housing plate 30.

First, the housing plate 30 having a plurality of holes is provided. An inner width of each of the holes formed in the housing plate 30 is configured to be smaller than the width of the electrically conductive contact pin 10. More specifically, the inner width of each of the holes provided in the housing plate 30 is configured to be smaller than the width between the pair of fixing portions 200.

With the configuration of the connecting portions 300 each of which is connected to a part of the pin portion 100 and connected to a part of each of the fixing portions 200, the pair of fixing portions 200 are elastically deformable in the width direction. The fixing portions 200 at a lower end of the electrically conductive contact pin 10 are compressed in the width direction so that the width thereof becomes smaller than the inner width of each of the holes provided in the housing plate 30, after which the electrically conductive contact pin 10 is inserted into each of the holes provided in the housing plate 30.

Then, the electrically conductive contact pin 10 is forcibly pushed into the hole provided in the housing plate 30 by pressing the electrically conductive contact pin 10 downwardly. The electrically conductive contact pin 10 is compressed in the width direction and moved to a lower portion of the hole provided in the housing plate 30.

When the lower fixing protrusion 211b passes through the hole of the housing plate 30, a stepped portion of the lower fixing protrusion 211b is supported on a lower surface of the housing plate 30 by a restoring force of the fixing portions 200, and a lower surface of the upper fixing protrusion 211a is supported on the lower surface of the housing plate 30. As a result, the electrically conductive contact pin 10 is fixedly installed in the housing plate 30, and installation of the electrically conductive contact pins 10 in the housing plate 30 is completed.

### Fourth Embodiment

Next, the fourth embodiment according to the present disclosure will be described. However, the embodiments described below will be mainly described in terms of characteristic elements in comparison with the third embodiment, and descriptions of the same or similar elements to the third embodiment will be omitted.

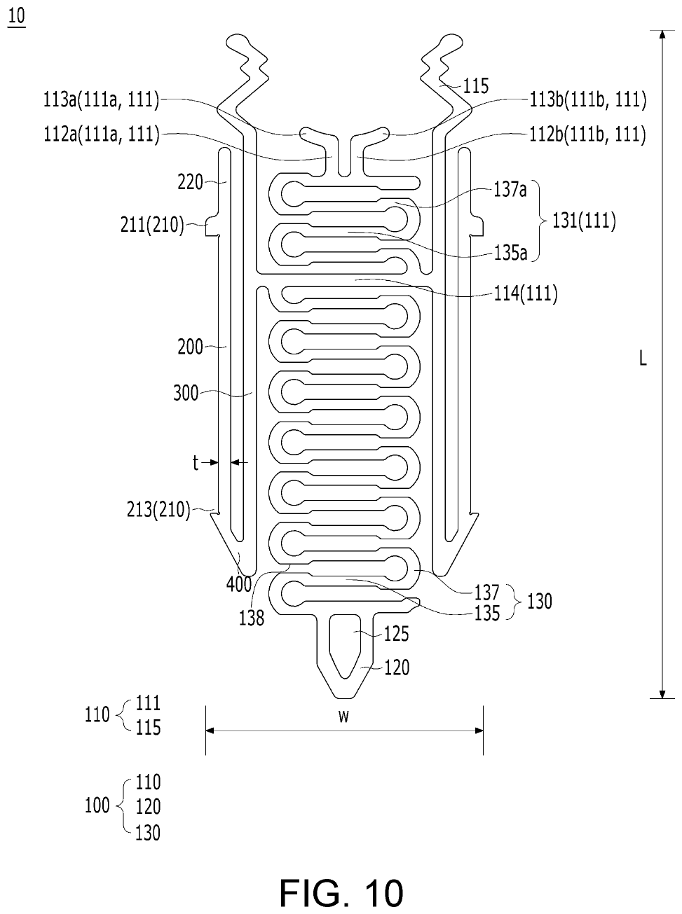

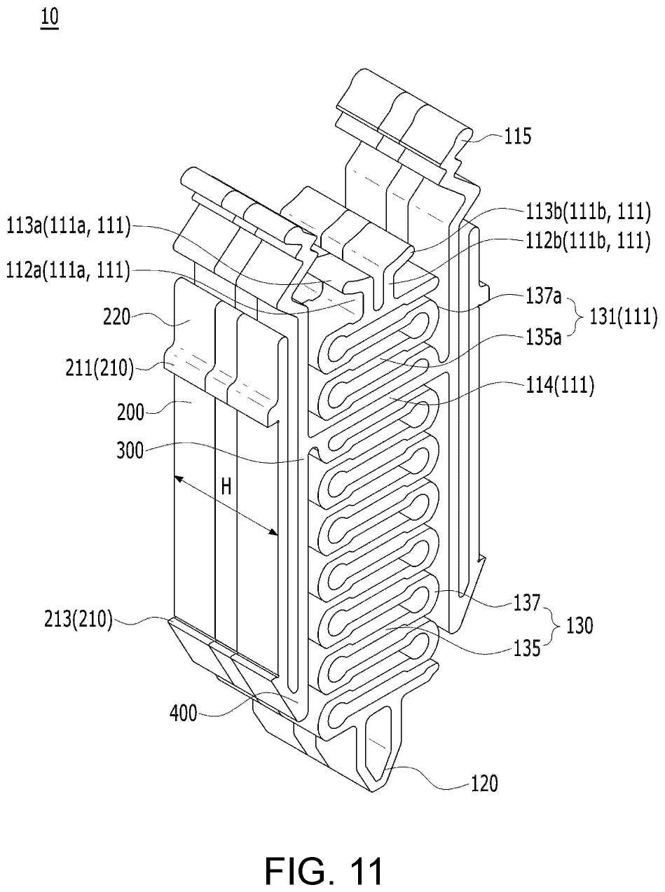

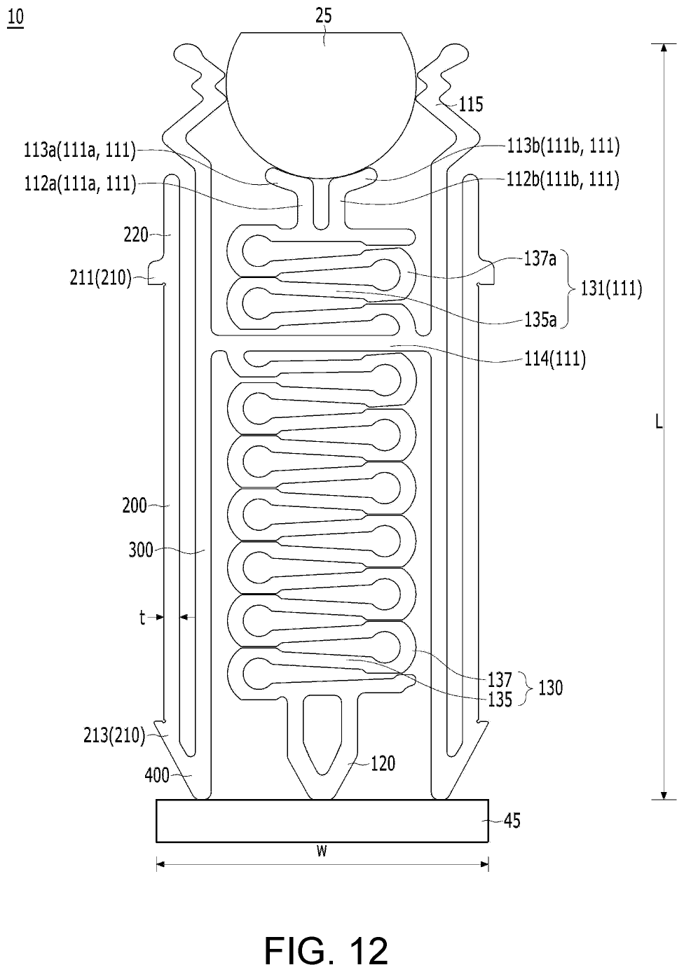

Hereinafter, an electrically conductive contact pin 10 according to the fourth embodiment of the present disclosure will be described with reference to FIGS. 10 to 12. FIG. 10 is a plan view illustrating the electrically conductive contact pin 10 according to the fourth embodiment of the present disclosure. FIG. 11 is a perspective view illustrating the electrically conductive contact pin according to the fourth embodiment of the present disclosure. FIG. 12 is a plan view illustrating a state in which an external terminal 25 is connected to the electrically conductive contact pin 10 according to the fourth embodiment of the present disclosure.

The electrically conductive contact pin 10 according to the fourth embodiment of the present disclosure remains the same as the electrically conductive contact pin 10 according to the third embodiment, except for the configuration of a first lower portion contact portion 101.

In the electrically conductive contact pin 10 according to the fourth embodiment of the present disclosure includes, the first lower portion contact portion 111 includes an upper elastic portion 131. The upper elastic portion 131 is formed by alternately connecting a plurality of upper straight portions 135a and a plurality of upper curved portions 137a. Each of the upper straight portions 135a connects the upper curved portions 137a adjacent in the left and right directions, and each of the upper curved portions 137a connects the upper straight portions 135a adjacent in the upper and lower directions. The upper straight portions 135a are disposed at a central portion of the upper elastic portion 131, and the upper curved portions 137a are disposed at outer peripheral portions of the upper elastic portion 131. The upper straight portions 135a are provided parallel to the width direction so that the upper curved portions 137a can be more easily deformed by contact pressure. With this, the upper elastic portion 131 has an appropriate contact pressure.

The upper elastic portion 131 has a lower portion connected to the boundary portion 114. More specifically, the upper curved portions 137a of the upper elastic portion 131 are connected to the boundary portion 114.

The upper elastic portion 131 has an upper portion connected to the first lower portion contact portion 111. More specifically, the first lower portion contact portion 111 includes a first-first lower portion contact portion 111a and a first-second lower portion contact portion 111b that are spaced apart from each other and provided symmetrically. Thus, the upper portion of the upper elastic portion 131 is connected to the first-first lower portion contact portion 111a and the first-second lower portion contact portion 111b.

As the first lower portion contact portion 111 is connected to the upper elastic portion 131, the external terminal 25 can provide an appropriate contact pressure by being elastically deformed when brought into contact with the first lower portion contact portion 111.

In the electrically conductive contact pin 10 according to the third embodiment, the boundary portion 114 is located above the upper fixing protrusion 211a. However, the electrically conductive contact pin 10 according to the fourth embodiment has a structural difference in that the boundary portion 114 is located between the upper fixing protrusion 211a and the lower fixing protrusion 211b. Due to the structural difference, a force pressing the side surface of the external terminal 125 by the first side portion contact portion 115 of the electrically conductive contact pin according to the fourth embodiment may be relatively small.

Referring to FIG. 12, during inspection, a lower end of the bent portion 400 is brought into contact with an upper surface of a circuit board 40 to serve as a stopper, thereby preventing the elastic portion 130 from being excessively compressed.

### Fifth Embodiment

Next, the fifth embodiment according to the present disclosure will be described. However, the embodiments described below will be mainly described in terms of characteristic elements in comparison with the first embodiment, and descriptions of the same or similar elements to the first embodiment will be omitted.

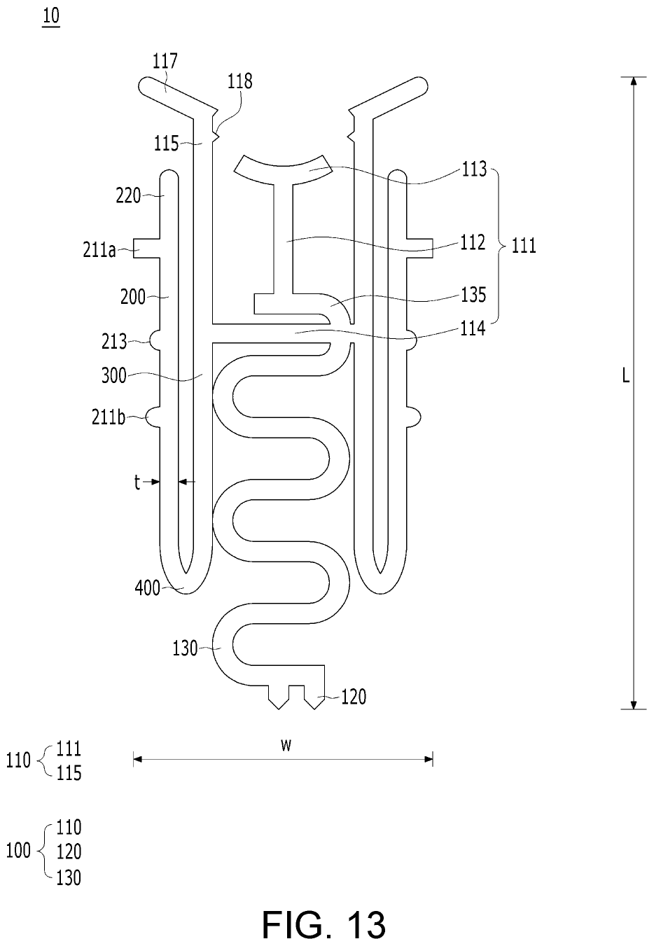

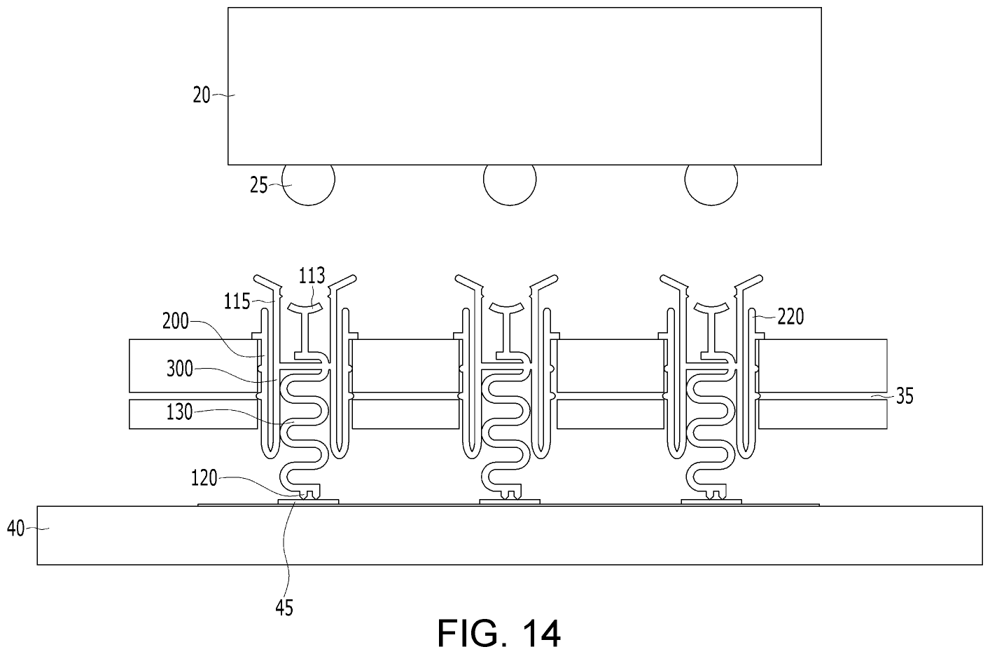

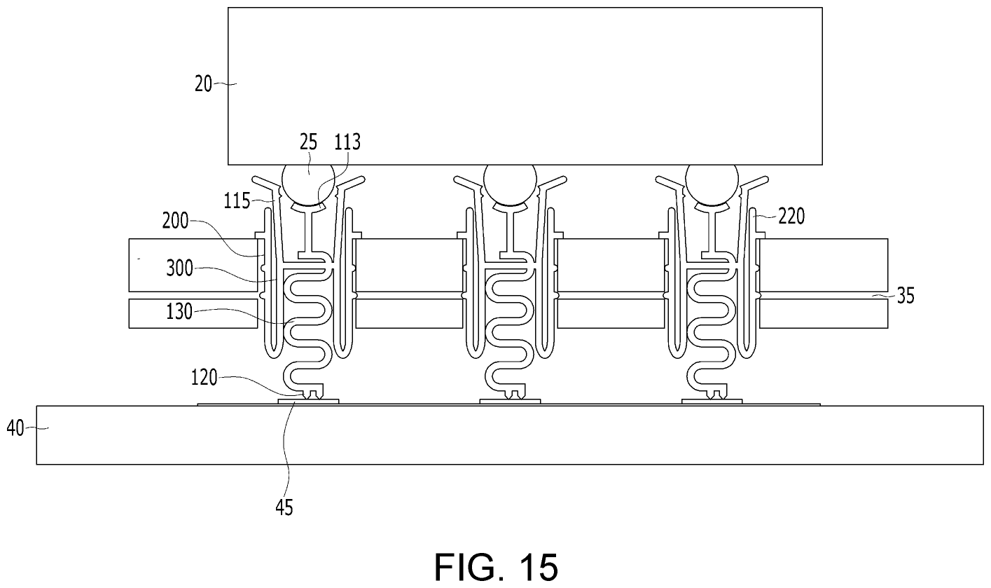

Hereinafter, an electrically conductive contact pin 10 according to the fifth embodiment of the present disclosure will be described with reference to FIGS. 13 to 15. FIG. 13 is a plan view illustrating the electrically conductive contact pin 10 according to the fifth embodiment of the present disclosure. FIG. 14 is a view illustrating a state before electrically conductive contact pins according to the fifth embodiment of the present disclosure are inspected in a state of being installed in a housing plate 30. FIG. 15 is a view illustrating a state in which the electrically conductive contact pins 10 according to the fifth embodiment of the present disclosure are inspected in a state of being installed in the housing plate 30.

In the electrically conductive contact pin 10 according to the fifth embodiment of the present disclosure, a first side portion contact portion 115 is formed to extend on the length axis of a connecting portion 300. A lower portion of the first side portion contact portion 115 is connected to an upper portion of the connecting portion 300 and a side portion of a boundary portion 114 at a point where they intersect with each other. In addition, the first side portion contact portion 115 includes a guide portion 117 at an upper portion thereof. The first side portion contact portion 115 includes an inner protrusion 118 protruding inwardly in the width direction.

A first lower portion contact portion 111 includes a lower surface support portion 113, a neck portion 112, and an auxiliary elastic portion 135 provided between the neck portion 112 and a boundary portion 114. The auxiliary elastic portion 135 allows the neck portion 112 and the lower surface support portion 113 to be elastically deformed by a pressing force. In this case, the neck portion 112 has a first end connected to the auxiliary elastic portion 135 and a second end connected to the lower surface support portion 113. With this, an impact generated when the lower surface support portion 113 and the spherical external terminal 25 are brought into contact with each other is alleviated. In addition, even when contact is not made at a correct position but at a displaced position, the lower surface support portion 113 can be deformed while surrounding a lower portion of the spherical external terminal 25. As a result, even when the spherical external terminal 25 is brought into contact with the lower surface support portion 113 at a misaligned position, the contact area can be increased.

A plurality of second contact portions 120 are provided in the form of protrusions to improve contact stability.

Hereinafter, a description will be given of a process for installing the electrically conductive contact pin 10 according to the fifth embodiment of the present disclosure in the housing plate 30.

First, the housing plate 30 having a plurality of holes is provided. An inner width of each of the holes formed in the housing plate 30 is configured to be smaller than the width of the electrically conductive contact pin 10. More specifically, the inner width of each of the holes provided in the housing plate 30 is configured to be smaller than the width between a pair of fixing portions 200.

With the configuration of a pair of connecting portions 300 each of which is connected to a part of the pin portion 100 and connected to a part of each of the fixing portions 200, the pair of fixing portions 200 are elastically deformable in the width direction. The fixing portions 200 at a lower end of the electrically conductive contact pin 10 are compressed in the width direction so that the width thereof becomes smaller than the inner width of each of the holes provided in the housing plate 30, after which the electrically conductive contact pin 10 is inserted into each of the holes provided in the housing plate 30.

Then, the electrically conductive contact pin 10 is forcibly pushed into the hole provided in the housing plate 30 by pressing the electrically conductive contact pin 10 downwardly. The electrically conductive contact pin 10 is compressed in the width direction and moved to a lower portion of the hole provided in the housing plate 30. In this case, the fixing portions 200 are moved downwardly with a small frictional force by friction reducing protrusions 213 provided on outer wall surfaces of the fixing portions 200 while being in close contact with an inner wall of the hole provided in the housing plate 30 by an elastic restoring force.

A fixing groove 35 is provided inside each of the holes provided in the housing plate 30. A lower fixing protrusion 211b is inserted into the fixing groove 30, and a lower surface of an upper fixing protrusion 211a is supported on a lower surface of the housing plate 30. As a result, the electrically conductive contact pin 10 is fixedly installed in the housing plate 30, and installation of the electrically conductive contact pins 10 in the housing plate 30 is completed.

In the electrically conductive contact pin 10 according to the fifth embodiment of the present disclosure, the first side portion contact portion 115 is formed to extend on the length axis of the connecting portion 300. The lower portion of the first side portion contact portion 115 is connected to the upper portion of the connecting portion 300 and the side portion of the boundary portion 114 at a point where they intersect with each other. In addition, the first side portion contact portion 115 includes the guide portion 117 at the upper portion thereof. The first side portion contact portion 115 includes the inner protrusion 118 protruding inwardly in the width direction.

### Sixth Embodiment

Next, the sixth embodiment according to the present disclosure will be described. However, the embodiments described below will be mainly described in terms of characteristic elements in comparison with the first embodiment, and descriptions of the same or similar elements to the first embodiment will be omitted.

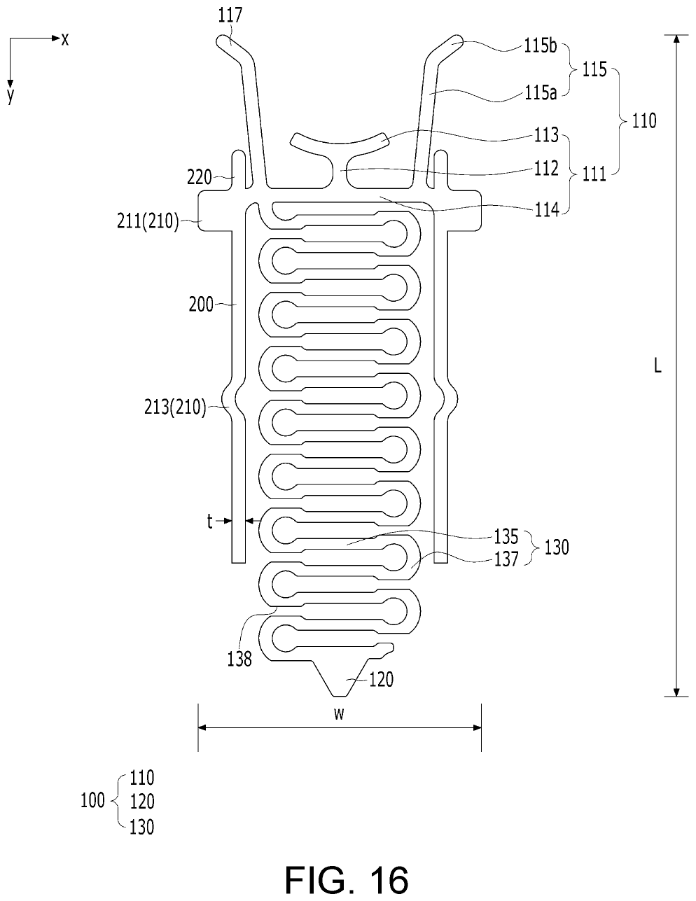

Hereinafter, an electrically conductive contact pin 10 according to the sixth embodiment of the present disclosure will be described with reference to FIG. 16. FIG. 16 is a plan view illustrating the electrically conductive contact pin 10 according to the sixth embodiment of the present disclosure.

In the electrically conductive contact pin 10 according to the first embodiment, the fixing portion 200 is indirectly coupled to the pin portion 100 through the connecting portion 300. However, the electrically conductive contact pin 10 according to the sixth embodiment has a structural difference from the first embodiment in that a fixing portion 200 is directly coupled to a pin portion 100. The fixing portion 200 is directly connected to a boundary portion 114. An upper end of the fixing portion 200 is connected to one side of the boundary portion 114, and a lower end of the fixing portion 200 serves as a free end.

Compared to the first embodiment, the electrically conductive contact pin 10 according to the sixth embodiment can have a reduced width W.

### Seventh Embodiment

Next, the seventh embodiment according to the present disclosure will be described. However, the embodiments described below will be mainly described in terms of characteristic elements in comparison with the second embodiment, and descriptions of the same or similar elements to the second embodiment will be omitted.

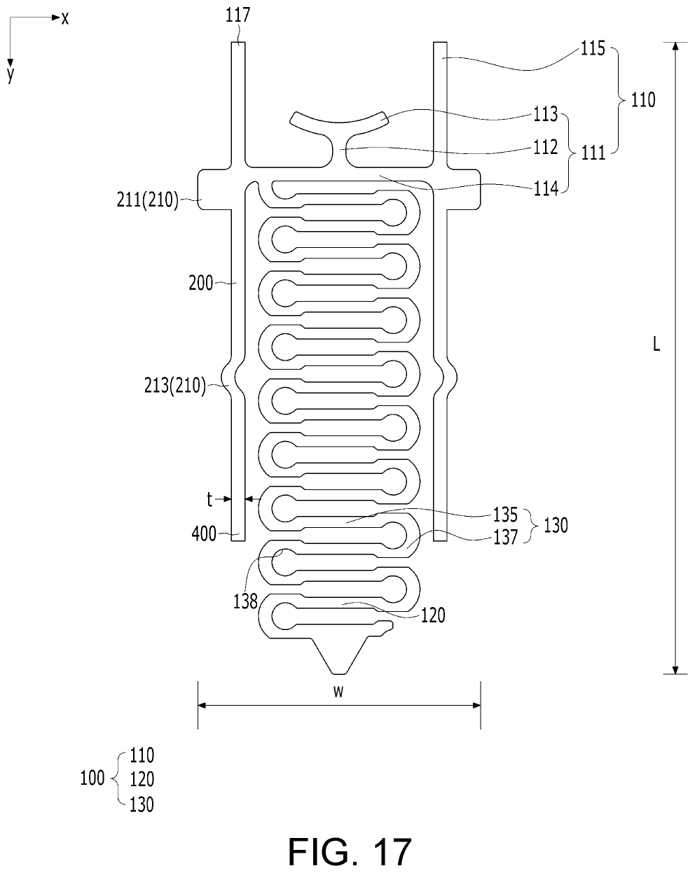

Hereinafter, an electrically conductive contact pin 10 according to the seventh embodiment of the present disclosure will be described with reference to FIG. 17. FIG. 17 is a plan view illustrating the electrically conductive contact pin 10 according to the seventh embodiment of the present disclosure.

In the electrically conductive contact pin 10 according to the second embodiment, the fixing portion 200 is indirectly coupled to the pin portion 100 through the connecting portion 300. However, the electrically conductive contact pin 10 according to the seventh embodiment has a structural difference from the second embodiment in that a fixing portion 200 is directly coupled to a pin portion 100. The fixing portion 200 is directly connected to a boundary portion 114. An upper end of the fixing portion 200 is connected to one side of the boundary portion 114, and a lower end of the fixing portion 200 serves as a free end. A first side portion contact portion 115 may be formed to extend upwardly from a point where the boundary portion 114 and the fixing portion 200 intersect with each other. In addition, the first side portion contact portion 115 may be formed on the same vertical line as the fixing portion 200.

Compared to the second embodiment, the electrically conductive contact pin 10 according to the seventh embodiment can have a reduced width W.

### Eighth Embodiment

Next, the eighth embodiment according to the present disclosure will be described. However, the embodiments described below will be mainly described in terms of characteristic elements in comparison with the third embodiment, and descriptions of the same or similar elements to the third embodiment will be omitted.

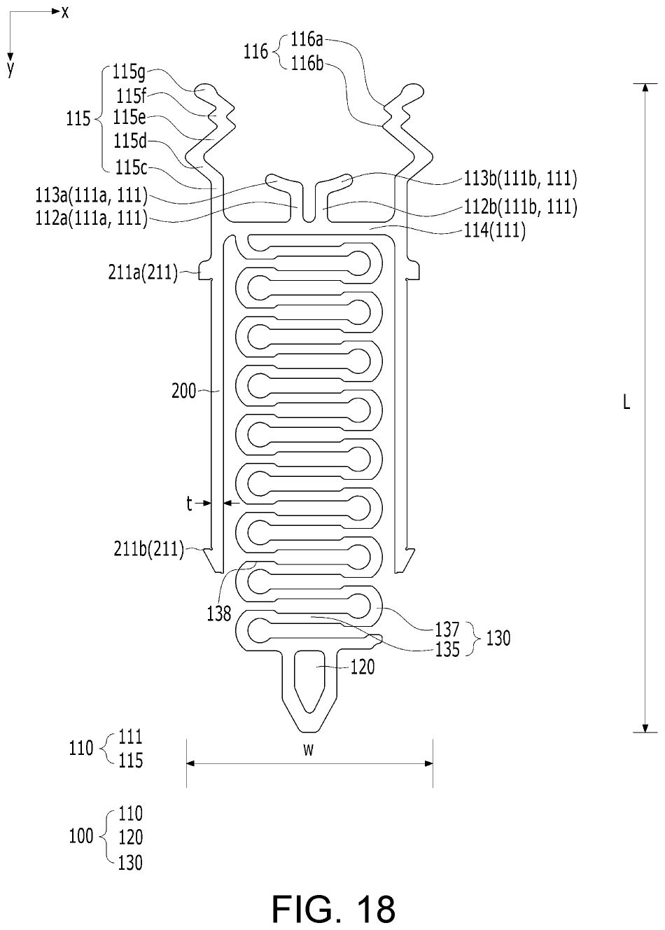

Hereinafter, an electrically conductive contact pin 10 according to the eighth embodiment of the present disclosure will be described with reference to FIG. 18. FIG. 18 is a plan view illustrating the electrically conductive contact pin 10 according to the eighth embodiment of the present disclosure.

In the electrically conductive contact pin 10 according to the third embodiment, the fixing portion 200 is indirectly coupled to the pin portion 100 through the connecting portion 300. However, the electrically conductive contact pin 10 according to the eighth embodiment has a structural difference from the third embodiment in that a fixing portion 200 is directly coupled to a pin portion 100. The fixing portion 200 is directly connected to a boundary portion 114. An upper end of the fixing portion 200 is connected to one side of the boundary portion 114, and a lower end of the fixing portion 200 serves as a free end. A first side portion contact portion 115 may be formed to extend upwardly from a point where the boundary portion 114 and the fixing portion 200 intersect with each other. In addition, the first side portion contact portion 115 may be formed on the same vertical line as the fixing portion 200.

Compared to the third embodiment, the electrically conductive contact pin 10 according to the eighth embodiment can have a reduced width W.

### Ninth Embodiment

Next, the ninth embodiment according to the present disclosure will be described. However, the embodiments described below will be mainly described in terms of characteristic elements in comparison with the fourth embodiment, and descriptions of the same or similar elements to the fourth embodiment will be omitted.

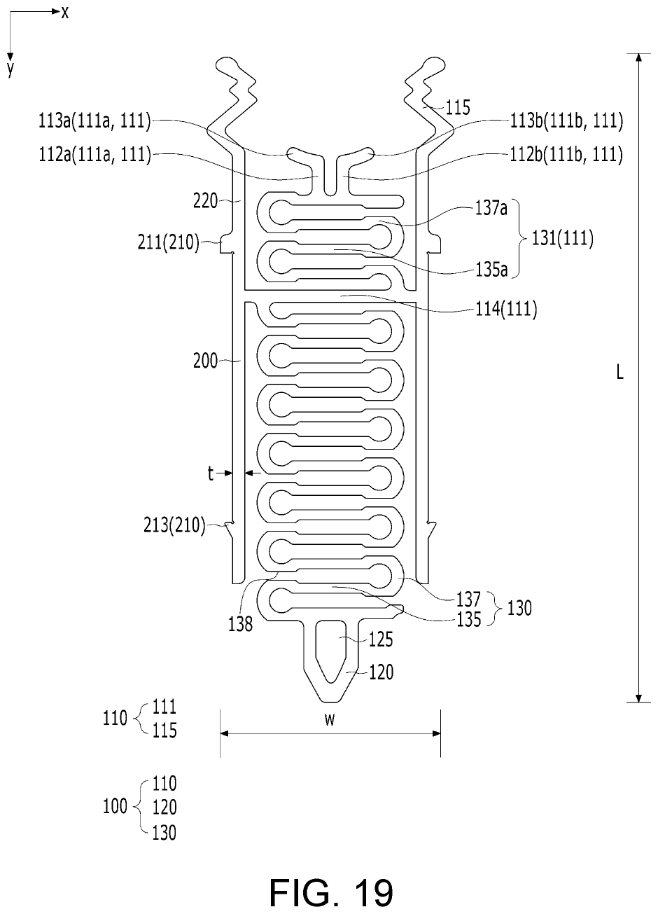

Hereinafter, an electrically conductive contact pin 10 according to the ninth embodiment of the present disclosure will be described with reference to FIG. 19. FIG. 19 is a plan view illustrating the electrically conductive contact pin 10 according to the ninth embodiment of the present disclosure.

In the electrically conductive contact pin 10 according to the fourth embodiment, the fixing portion 200 is indirectly coupled to the pin portion 100 through the connecting portion 300. However, the electrically conductive contact pin 10 according to the ninth embodiment has a structural difference from the fourth embodiment in that a fixing portion 200 is directly coupled to a pin portion 100. The fixing portion 200 is directly connected to a boundary portion 114. An upper end of the fixing portion 200 is connected to one side of the boundary portion 114, and a lower end of the fixing portion 200 serves as a free end. A first side portion contact portion 115 may be formed to extend upwardly from a point where the boundary portion 114 and the fixing portion 200 intersect with each other. In addition, the first side portion contact portion 115 may be formed on the same vertical line as the fixing portion 200. Meanwhile, in the fourth embodiment, the fixing protrusion 211 formed on the fixing portion 200 is provided on the first side portion contact portion 115. Unlike this, in this embodiment, a fixing protrusion 211 may be provided on the fixing portion 200.

Compared to the fourth embodiment, the electrically conductive contact pin 10 according to the ninth embodiment can have a reduced width W.

### Tenth Embodiment

Next, the tenth embodiment according to the present disclosure will be described. However, the embodiments described below will be mainly described in terms of characteristic elements in comparison with the fifth embodiment, and descriptions of the same or similar elements to the fifth embodiment will be omitted.

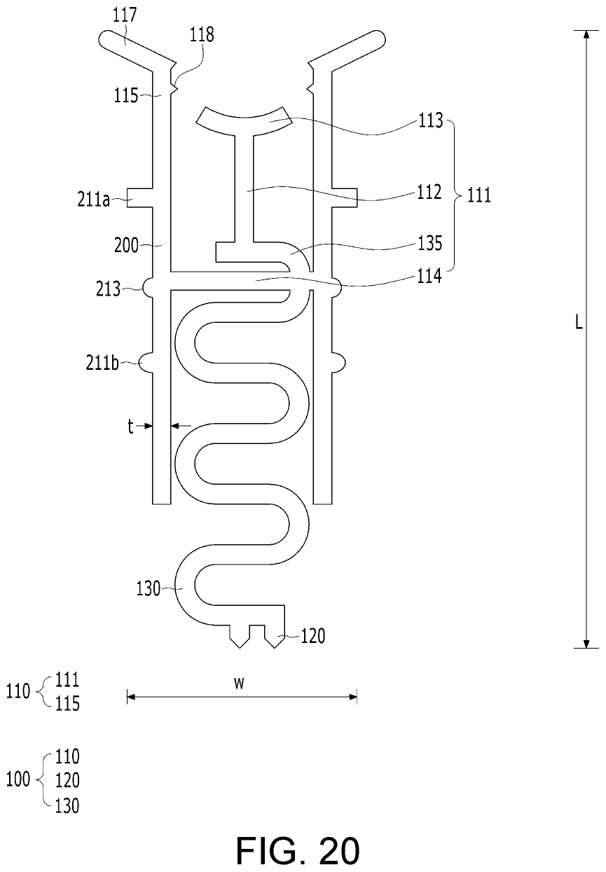

Hereinafter, an electrically conductive contact pin 10 according to the tenth embodiment of the present disclosure will be described with reference to FIG. 20. FIG. 20 is a plan view illustrating the electrically conductive contact pin 10 according to the tenth embodiment of the present disclosure.

In the electrically conductive contact pin 10 according to the fifth embodiment, the fixing portion 200 is indirectly coupled to the pin portion 100 through the connecting portion 300. However, the electrically conductive contact pin 10 according to the tenth embodiment has a structural difference from the fifth embodiment in that a fixing portion 200 is directly coupled to a pin portion 100. The fixing portion 200 is directly connected to a boundary portion 114. An upper end of the fixing portion 200 is connected to one side of the boundary portion 114, and a lower end of the fixing portion 200 serves as a free end. A first side portion contact portion 115 may be formed to extend upwardly from a point where the boundary portion 114 and the fixing portion 200 intersect with each other. In addition, the first side portion contact portion 115 may be formed on the same vertical line as the fixing portion 200. Meanwhile, in the fifth embodiment, the upper fixing protrusion 211a formed on the fixing portion 200 is provided on the first side portion contact portion 115. Unlike this, in this embodiment, an upper fixing protrusion 211a may be provided on the fixing portion 200.

Compared to the fifth embodiment, the electrically conductive contact pin 10 according to the tenth embodiment can have a reduced width W.

### Eleventh Embodiment

Next, the eleventh embodiment according to the present disclosure will be described. However, the embodiments described below will be mainly described in terms of characteristic elements in comparison with the fourth embodiment, and descriptions of the same or similar elements to the fourth embodiment will be omitted.

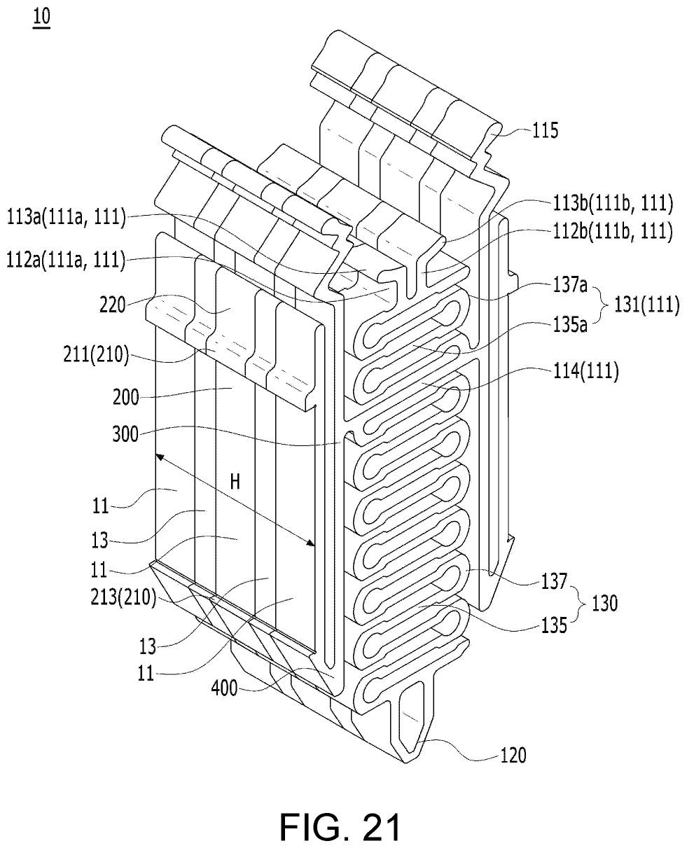

Hereinafter, an electrically conductive contact pin 10 according to the eleventh embodiment of the present disclosure will be described with reference to FIG. 21. FIG. 21 is a perspective view illustrating the electrically conductive contact pin 10 according to the eleventh embodiment of the present disclosure.

Unlike the fourth embodiment, the electrically conductive contact pin 10 according to the eleventh embodiment is provided by sequentially stacking a first metal 11, a second metal 13, and a first metal 11, a second metal 13, and a first metal 11, and the number of stacked layers are five. As a modified example of the eleventh embodiment, the electrically conductive contact pin 10 may be provided by stacking a larger number of layers. The number of layers in which the first metal 11 and the second metal 13 are stacked may be five or more. Thus, the content of the second metal 13 can be increased, thereby improving the current carrying capacity of the electrically conductive contact pin 10.

Meanwhile, the overall thickness H and the overall width W of the electrically conductive contact pin 10 may be configured to be substantially the same. As a result, the overall thickness H of a first contact portion 110 is increased, so that contact stability with an external terminal 25 can be improved. In addition, an elastic portion 130 is provided in the form of a bent leaf spring formed by bending a thin plate a plurality of times. Thus, when the elastic portion 130 is deformed, deformation stability can be improved, thereby preventing the elastic portion 130 from expanding in the front and rear directions.

The configuration adopted in the eleventh embodiment can also be applied to the other embodiments. Therefore, in the other embodiments, the first metal 11 and the second metal 13 may be staked in a number greater than three layers exemplarily illustrated in the drawings of each embodiment. Also, the overall thickness H and the overall width W of the electrically conductive contact pin 10 may be substantially the same.

### Twelfth Embodiment

Next, the twelfth embodiment according to the present disclosure will be described. However, the embodiments described below will be mainly described in terms of characteristic elements in comparison with the fourth embodiment, and descriptions of the same or similar elements to the fourth embodiment will be omitted.

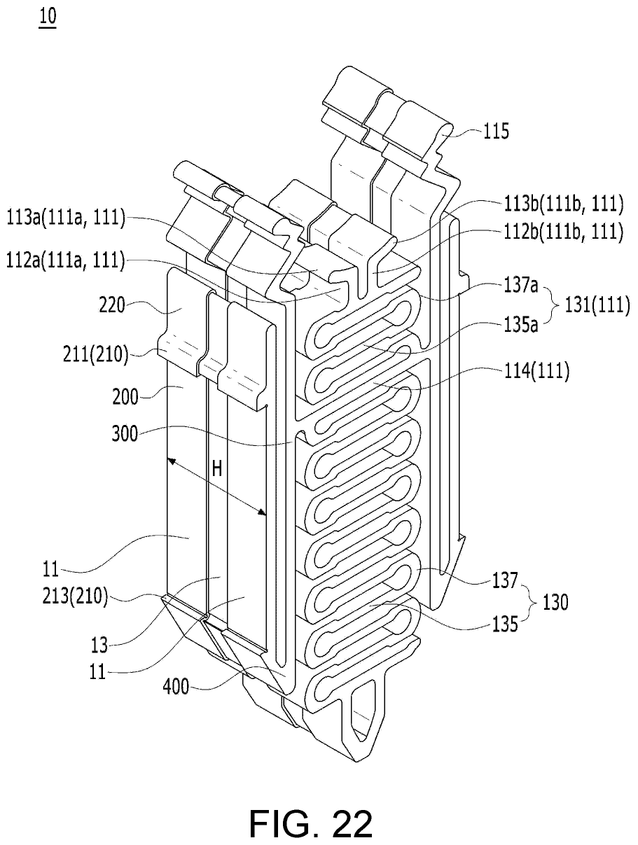

Hereinafter, an electrically conductive contact pin 10 according to the twelfth embodiment of the present disclosure will be described with reference to FIG. 22. FIG. 22 is a perspective view illustrating the electrically conductive contact pin 10 according to the twelfth embodiment of the present disclosure.

The electrically conductive contact pin 10 according to the twelfth embodiment includes a first metal 11 and a second metal 213 alternately stacked. The first metal 11 and the second metal 13 are not provided on the same plane. More specifically, in at least a partial surface area of the electrically conductive contact pin 10, the second metal 13 does not further protrude from the surface than the first metal 11. In other words, in the twelfth embodiment, unlike the fourth embodiment, the first metal 11 further protrudes from the surface than the second metal 13. The second metal 13 provided between first metals 11 does not further protrude from the surface than the first metals 11. This may be implemented by selectively etching only the second metal 13 after a plating process is completed.

Since the second metal 13 has a lower hardness than the first metals 11, when the first metals 11 and the second metal 13 are provided on the same plane, durability of the electrically conductive contact pin 10 may be reduced as the second metal 13 is worn. Thus, with the configuration in which the second metal 13 does not further protrude than the first metals 11 in order to prevent the second metal 13 from being brought into contact with an external object, wear resistance against contact can be improved.

The configuration in which the second metal 13 does not further protrude than the first metals 11 may be provided entirely in the electrically conductive contact pin 10, or provided selectively in a portion where the second metal 13 is substantially brought into contact with the external object.

When the configuration in which the second metal 13 does not further protrude than the first metals 11 is provided entirely in the electrically conductive contact pin 10, the content of the second metal 13 is reduced. This may be disadvantageous in terms of the current carrying capacity of the electrically conductive contact pin 10. Thus, when the configuration in which the second metal 13 does not further protrude than the first metals 11 is provided selectively in the portion where the second metal 13 is substantially brought into contact with the external object, this can be advantageous in terms of the current carrying capacity.

When the configuration in which the second metal 13 does not further protrude than the first metals 11 is provided selectively in the portion where the second metal 13 is substantially brought into contact with the external object, it is preferably provided in a first contact portion 110, a second contact portion 120, and/or a fixing portion 200.

In a surface of the first contact portion 110 brought into contact with an external terminal of an inspection object 20, more specifically, a widthwise inner surface of a first side portion contact portion 115 and/or an upper surface of a first lower portion contact portion 111, the second metal 13 may not further protrude than the first metals 11 and may be stepped inwardly. With this, the external terminal 25 of the inspection object 20 is brought into contact with the first metals 11 but may not be brought into contact with the second metal 13. As a result, the number of contact points between the external terminal 25 of the inspection object 20 and the first contact portion 110 is increased, thereby improving contact stability.

Meanwhile, the second contact portion 110 is electrically connected to a terminal 45 of a circuit board 40. In a lower surface of the second contact portion 110, the second metal 13 may not further protrude than the first metals 11 and may be stepped inwardly. With this, the number of contact points is increased, thereby improving contact stability.

Meanwhile, the fixing portion 200 is fixedly installed in a housing plate 30. In a side surface of the fixing portion 200 facing the housing plate 30, the second metal 13 may not further protrude than the first metals 11 and may be stepped inwardly. With this, wear caused by contact can be minimized.

The configuration adopted in the twelfth embodiment can also be applied to the other embodiments. Therefore, in the other embodiments, in at least a partial surface area of the electrically conductive contact pin 10, the second metal 13 may not further protrude from the surface than the first metals 11.

Modified Examples of First Contact Portions

Hereinafter, modified examples of the first contact portions 110 in the electrically conductive contact pins 10 according to the above-described embodiments of the present disclosure will be described.

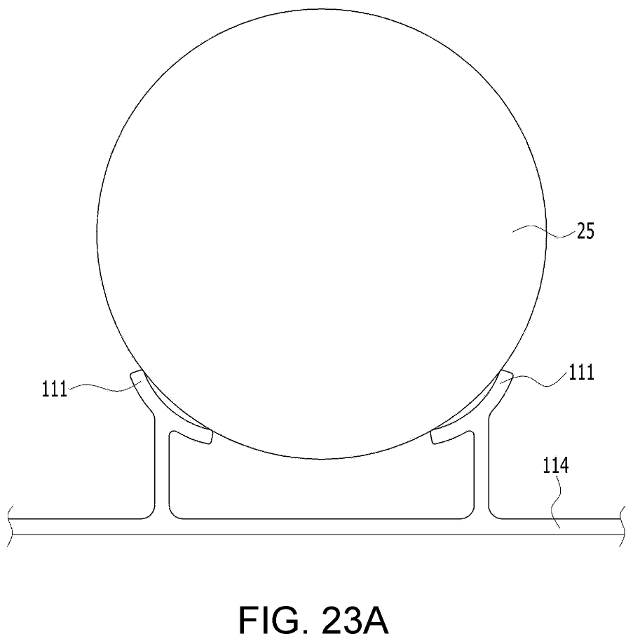

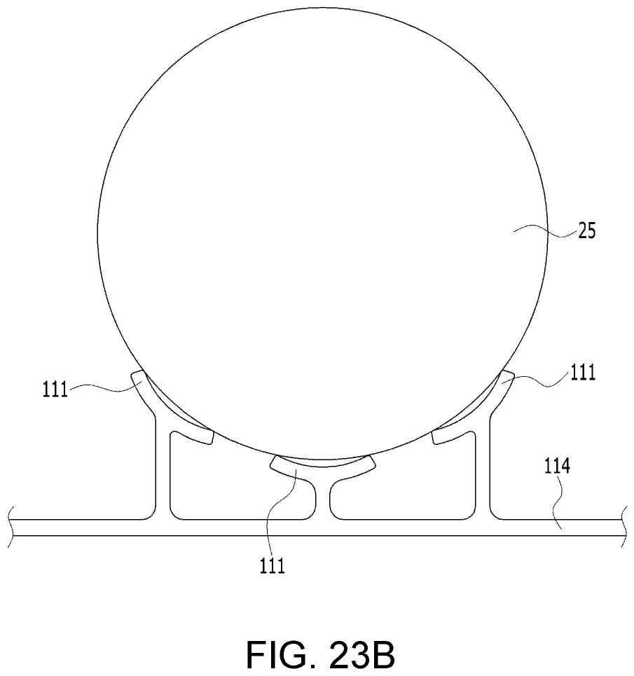

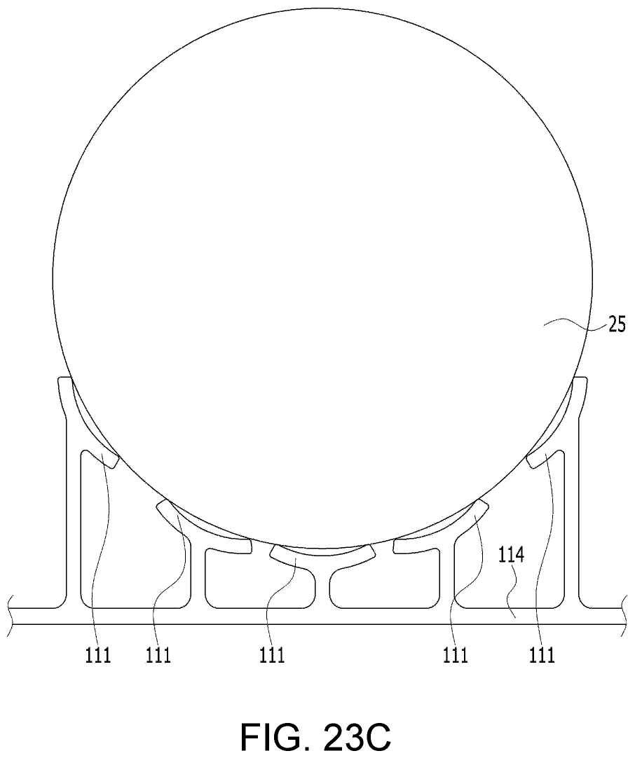

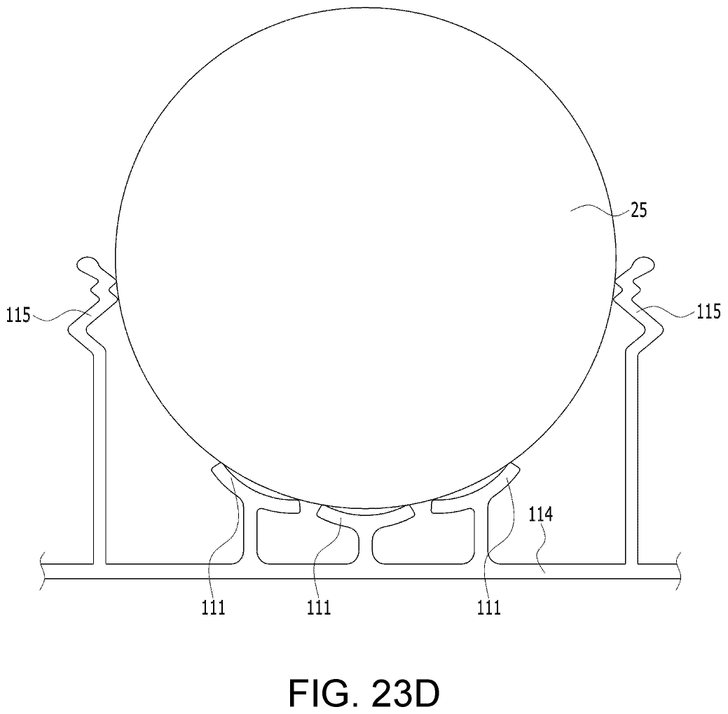

FIGS. 23A to 23D are views illustrating the modified examples of the first contact portions 110 in the electrically conductive contact pins 10 according to the embodiments of the present disclosure.

Referring to FIG. 23A, two first lower portion contact portions 111 are provided to be individually brought into contact with an external terminal 25. In addition, a lower surface support portion 113 of each first contact portion 110 is formed to have a radius of curvature, and each lower surface support portion 113 may provide at least two or more contact areas. More specifically, the radius of curvature of the lower surface support portion 113 may be configured to be smaller than that of the external terminal 25 so that the external terminal 25 is brought into contact with each lower surface support portion 113 in at least two areas. The two first lower portion contact portions 111 are provided in the form of a planar plate, and each lower surface support portion 113 is configured to have a radius of curvature smaller than that of the spherical external terminal 25. Thus, line contact is made with the external terminal 25 at at least four points, thereby improving contact stability.

Referring to FIG. 23B, three first lower portion contact portions 111 are provided to be individually brought into contact with an external terminal 25. The three first lower portion contact portions 111 are provided in the form of a planar plate, and each lower surface support portion 113 is configured to have a radius of curvature smaller than that of the spherical external terminal 25. Thus, line contact is made with the external terminal 25 at at least six points, thereby improving contact stability.

Referring to FIG. 23C, five first lower portion contact portions 111 are provided to be individually brought into contact with an external terminal 25. The five first lower portion contact portions 111 are provided in the form of a planar plate, and each lower surface support portion 113 is configured to have a radius of curvature smaller than that of the spherical external terminal 25. Thus, line contact is made with the external terminal 25 at at least ten points, thereby improving contact stability.

FIGS. 23A to 23C illustrate that the number of the first lower portion contact portions 111 is two, three, and five. However, the number of the first lower portion contact portions 111 is not limited thereto. As such, the electrically conductive contact pin 10 includes a plurality of first lower portion contact portions 111 so that the first lower portion contact portions 111 are individually brought into contact with the external terminal 25, thereby improving contact stability.

Referring to FIG. 23D, the electrically conductive contact pin 10 includes a plurality of first lower portion contact portions 111 and a pair of first side portion contact portions 115. The three first lower portion contact portions 111 and the pair of first side portion contact portions 115 are provided in the form of a planar plate, each lower surface support portion 113 is configured to have a radius of curvature smaller than that of a spherical external terminal 25, and each first side portion contact portion 115 has a plurality of protruding tips. Thus, line contact is made with the external terminal 25 at at least ten points, thereby improving contact stability.

As described above, with the configuration in which the first contact portion 110 provides a plurality of contact areas making contact with the external terminal 25 and each contact area of the first contact portion 110 is provided in the form of a planar plate, a linear contact area is provided along the thickness direction of the electrically conductive contact pin 10.

In addition, the plurality of contact areas are provided at different positions in the length direction of the electrically conductive contact pin 10. For example, as illustrated in FIGS. 23B and 23C, the contact areas provided by the first lower portion contact portion 111 located centrally is provided at lower positions than the contact areas provided by the first lower portion contact portions 111 located laterally thereto. In addition, as illustrated in FIG. 23D, the contact areas provided by the plurality of first lower portion contact portions 111 are provided at lower positions than the contact areas provided by the pair of first side portion contact portions 115.

The plurality of contact areas provided by the first contact portion 110 can make contact with an outer surface of the spherical external terminal 25 while surrounding the outer surface, thereby improving contact stability with the external terminal 25.

Manufacturing Method for Electrically Conductive Contact Pin

Hereinafter, a manufacturing method for the electrically conductive contact pins according to the above-described embodiments of the present disclosure will be described.

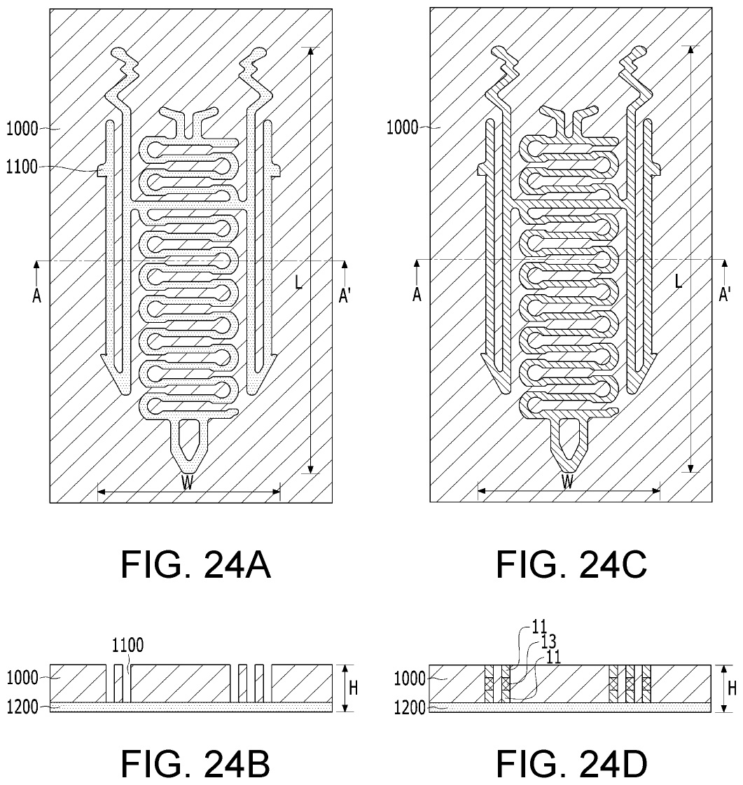

FIG. 24a is a plan view illustrating a mold 1000 in which an inner space 1100 is formed. FIG. 24b is a sectional view taken along line A-A′ of FIG. 24a. The shape of the inner space 1100 illustrated in FIG. 24a is equal to that of the fourth embodiment, but is not limited thereto, and may be configured in the shape of an embodiment possible by any one of the above-described embodiments or a combination thereof.

The mold 1000 may be made of an anodic aluminum oxide film, a photoresist, a silicon wafer, or a material similar thereto. However, a preferred material for the mold 1000 is the anodic aluminum oxide film. The anodic aluminum oxide film means a film formed by anodizing a metal as a base material, and pores mean holes formed in the process of forming the anodic aluminum oxide film by anodizing the metal. For example, when the metal as the base material is aluminum (Al) or an aluminum alloy, the anodization of the base material forms the anodic aluminum oxide film consisting of anodized aluminum (Al₂O₃) on a surface of the base material. However, the metal is not limited thereto, and includes Ta, Nb, Ti, Zr, Hf, Zn, W, Sb, or an alloy of these metals. The resulting anodic aluminum oxide film includes a barrier layer in which no pores are formed therein vertically, and a porous layer in which pores are formed therein. After removing the base material on which the anodic aluminum oxide film having the barrier layer and the porous layer is formed, only the anodic aluminum oxide film consisting of anodized aluminum (Al₂O₃) remains. The anodic aluminum oxide film may have a structure in which the barrier layer formed during the anodization is removed to expose the top and bottom of the pores, or a structure in which the barrier layer formed during the anodization remains to close one of the top and bottom of the pores.

The anodic aluminum oxide film has a coefficient of thermal expansion of 2 to 3 ppm/° C. With this range, the anodic aluminum oxide film only undergoes a small amount of thermal deformation due to temperature when exposed to a high temperature environment. Thus, even when the electrically conductive contact pin 10 is manufactured in a high temperature environment, a precise electrically conductive contact pin 10 can be manufactured without thermal deformation.

Since the electrically conductive contact pins 10 according to the embodiments of the present disclosure are manufactured using the mold 1000 made of the anodic aluminum oxide film instead of a photoresist mold, there is an effect of realizing shape precision and a fine shape, which were limited in realization with the photoresist mold. In addition, when the conventional photoresist mold is used, an electrically conductive contact pin with a thickness of 40 μm can be manufactured, but when the mold 1000 made of the anodic aluminum oxide film is used, the electrically conductive contact pin 10 with a thickness in the range of 100 μm to 200 μm can be manufactured.

A seed layer 1200 is provided on a lower surface of the mold 1000. The seed layer 1200 may be provided on the lower surface of the mold 1000 before the inner space 1100 is formed in the mold 1000. Meanwhile, a support substrate (not illustrated) is formed under the mold 1000 to improve handling of the mold 1000. In this case, the seed layer 1200 may be formed on an upper surface of the support substrate, and then the mold 1000 having the inner space 1100 may be coupled to the support substrate. The seed layer 1200 may be made of copper (Cu), and may be formed by a deposition method.

The inner space 1100 may be formed by wet-etching the mold 1000 made of the anodic aluminum oxide film. To this end, a photoresist may be provided on the upper surface of the mold 1000 and patterned, and then the anodic aluminum oxide film in a patterned and open area may react with an etchant to form the inner space 1100.

Thereafter, an electroplating process is performed on the inner space 1100 of the mold 1000 to form an electrically conductive contact pin 10. FIG. 22c is a plan view illustrating the inner space 1100 on which the electroplating process is performed. FIG. 22d is a sectional view taken along line A-A′ of FIG. 22c.

During the electroplating process, a metal layer is formed while growing in the thickness direction of the mold 1000. Thus, the metal layer thus formed has a uniform cross-sectional shape in the thickness direction of the electrically conductive contact pin 10, and a plurality of metal layers are stacked in the thickness direction of the electrically conductive contact pin 10. The metal layers include a first metal 11 and a second metal 13. The first metal 11 is a metal having relatively high wear resistance compared to the second metal 13, and may be selected from the group consisting of rhodium (Rd), platinum (Pt), iridium (Ir), palladium, and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn), a nickel-cobalt (NiCo), and a nickel-tungsten (NiW) alloy. The second metal 13 is a metal having relatively high electrical conductivity compared to the first metal 11, and may be selected from the group consisting of copper (Cu), silver (Ag), gold (Au), and an alloy of these metals.

The first metal 11 is provided on each of a lower surface and an upper surface of the electrically conductive contact pin 10 in the thickness direction, and the second metal 13 is provided between the respective first metals 11. For example, the electrically conductive contact pin 10 may be provided by sequentially stacking the first metal 11, the second metal 13, and the first metal 11, and the number of stacked layers may be at least three.

After the plating process is completed, the temperature is raised to a high temperature and pressure is applied to pressurize the metal layers on which the plating process is completed so that the first metal 11 and the second metal 13 are made denser. When a photoresist is used as a mold, the process of raising the temperature to a high temperature and applying pressure cannot be performed because the photoresist exists around the metal layers after the plating process is completed. On the contrary, according to the embodiment of the present disclosure, since the mold 1000 made of the anodic aluminum oxide film is provided around the metal layers on which the plating process is completed, even when the temperature is raised to a high temperature, it is possible to densify the first metal 11 and the second metal 13 with minimized deformation because of the low coefficient of thermal expansion of the anodic aluminum oxide film. Thus, it is possible to obtain the first metal 11 and the second metal 13 with a higher density compared to the technique using the photoresist as a mold.

When the electroplating process is completed, the mold 1000 and the seed layer 1200 are removed. When the mold 1000 is made of the anodic aluminum oxide film, the mold 1000 is removed using a solution that selectively reacts with the anodic aluminum oxide film. In addition, when the seed layer 1200 is made of copper (Cu), the seed layer 1200 is removed using a solution that selectively reacts with copper (Cu).

According to the technique for manufacturing a pin by electroplating using a photoresist as a mold, it is difficult to sufficiently increase the height of the mold only with the use of a single-layer photoresist. As a result, it is also difficult to sufficiently increase the thickness of the electrically conductive contact pin. The electrically conductive contact pin needs to be manufactured with a predetermined thickness in consideration of electrical conductivity, restoring force, brittle fracture, etc. In order to increase the thickness of the electrically conductive contact pin, a mold in which photoresists are stacked in multiple layers may be used. However, in this case, each photoresist layer is slightly stepped, so that a problem occurs in that a side surface of the electrically conductive contact pin is not formed vertically and a stepped area minutely remains. In addition, when the photoresists are stacked in multiple layers, it is difficult to accurately reproduce the shape of the electrically conductive contact pin having a dimension range of equal to or less than several to several tens of μm. In particular, in the case of the photoresist mold, the photoresist is provided between inner spaces thereof. When the width of the photoresist provided between the inner spaces is equal to or less than 15 μm, the photoresist is not formed properly. In particular, when the height thereof is large compared to the width thereof, a problem occurs in that a standing state of the photoresist at the corresponding position is not properly maintained.

Therefore, when the photoresist is used as a mold, it may be difficult to make the ratio of the actual width of the plates constituting the electrically conductive contact pin 10 to the overall thickness H in the range of 1:5 to 1:30.

However, in manufacturing the electrically conductive contact pins 10 according to the embodiments of the present disclosure by using the mold 1000 made of the anodic aluminum oxide film, there is an advantage in that it is easy to make the ratio of the actual width of the plates constituting the electrically conductive contact pin 10 to the overall thickness H in the range of 1:5 to 1:30. Since the anodic aluminum oxide film is provided between inner spaces 1100 of the mold 1000 made of the anodic aluminum oxide film, the anodic aluminum oxide film can maintain a standing state even when the distance between the inner spaces 1100 is in the range of 5 μm to 15 μm. As such, the use of the mold 1000 made of the anodic aluminum oxide film makes it possible to make the overall thickness H of the electrically conductive contact pin 10 in the range of 100 μm to 200 μm, and to make the actual width t of the plates small in the range of 5 μm to 15 μm. With this, it is possible to provide the electrically conductive contact pin 10 that can cope with high-frequency characteristics.

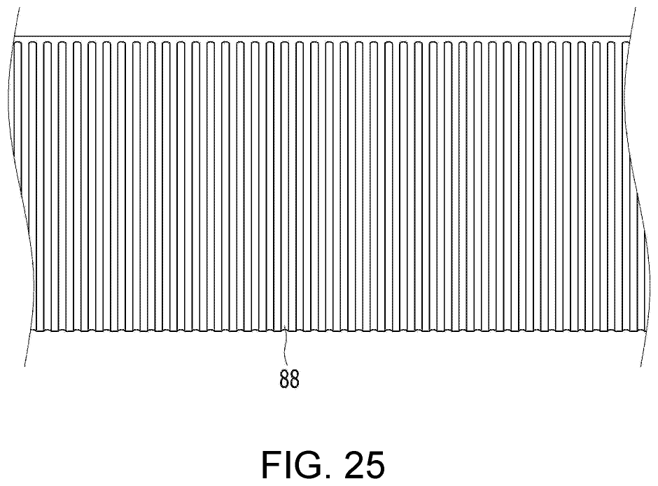

Referring to FIG. 25, each of the electrically conductive contact pins 100 according to the embodiments of the present disclosure includes a plurality of fine trenches 88 provided in a side surface thereof. The fine trenches 88 are formed to extend in the thickness direction of the electrically conductive contact pin 10 in the side surface of the electrically conductive contact pin 10. Here, the thickness direction of the electrically conductive contact pin 10 means a direction in which a metal filling material grows during electroplating.

The fine trenches 88 have a depth in the range of 20 nm to 1 μm and a width in the range of 20 nm to 1 μm. Here, because the fine trenches 88 are resulted from the formation of the pores formed during the manufacture of the mold made of the anodic aluminum oxide film, the width and depth of the fine trenches 88 are equal or less than the diameter of the pores formed in the mold 1000 made of the anodic aluminum oxide film. On the other hand, in the process of forming the inner space 1100 in the mold 1000 made of the anodic aluminum oxide film, portions of the pores of the mold 1000 made of the anodic aluminum oxide film may be crushed by an etchant to at least partially form a fine trench 88 having a depth greater than the diameter of the pores formed during the anodization.

Since the mold 1000 made of the anodic aluminum oxide film includes a large number of pores, at least a portion of the mold 1000 made of the anodic aluminum oxide film is etched to form the inner space 1100, and the metal filling material is formed in the inner space 1100 by electroplating, the fine trenches 88 are formed on the side surface of the electrically conductive contact pin 10 as a result of contact between the contact pin and the pores of the mold 1000 made of the anodic aluminum oxide film.

The fine trenches 88 as described above can contribute to increasing the surface area of the side surface of the electrically conductive contact pin 10. In addition, with the configuration of the fine trenches 88 formed in the side surface of the electrically conductive contact pin 10, heat generated in the electrically conductive contact pin 10 can be rapidly dissipated, thereby suppressing a rise in the temperature of the electrically conductive contact pin 10. In addition, with the configuration of the fine trenches 88 formed in the side surface of the electrically conductive contact pin 10, the torsional resistance ability of the electrically conductive contact pin against deformation can be improved.

A plating film made of gold (Au) may be additionally formed on a surface of each of the electrically conductive contact pins 10 according to the above-described embodiments to further improve the current carrying capacity.

Although the exemplary embodiments of the present disclosure have been described for illustrative purposes, those skilled in the art will appreciate that various modifications, additions, and substitutions are possible, without departing from the scope and spirit of the present disclosure as disclosed in the accompanying claims.

### DESCRIPTION OF THE REFERENCE NUMERALS IN THE DRAWINGS

10: electrically conductive contact pin
100: pin portion
110: first contact portion
120: second contact portion
130: elastic portion
200: fixing portion
210: protrusion
300: connecting portion

1. An electrically conductive contact pin, comprising:
a pin portion comprising a first contact portion, a second contact portion, and an elastic portion between the first contact portion and the second contact portion;
a fixing portion provided outside the pin portion; and
a connecting portion provided between the pin portion and the fixing portion to connect the pin portion and the fixing portion to each other.

2. The electrically conductive contact pin of claim 1, wherein the pin portion, the fixing portion, and the connecting portion are integrally provided with each other.

3. The electrically conductive contact pin of claim 1, wherein the electrically conductive contact pin is elastically deformable in a length direction and at the same time elastically deformable in a width direction.

4. The electrically conductive contact pin of claim 1, wherein the pin portion is relatively displaceable with respect to the fixing portion.

5. The electrically conductive contact pin of claim 1, wherein the first contact portion comprises: a first lower portion contact portion brought into contact with a lower portion of a contact object; and
a first side portion contact portion brought into contact with a side portion of the contact object.

6. The electrically conductive contact pin of claim 1, wherein the first contact portion comprises a first side portion contact portion brought into contact with a side portion of a contact object.

7. The electrically conductive contact pin of claim 1, wherein the connecting portion is formed to extend in the same length direction as a length direction of the fixing portion.

8. The electrically conductive contact pin of claim 1, wherein the connecting portion is relatively movable with respect to the fixing portion so that a separation space between the fixing portion and the connecting portion is changed.

9. The electrically conductive contact pin of claim 1, wherein the connecting portion is connected to a lower end of the fixing portion.

10. The electrically conductive contact pin of claim 1, wherein the connecting portion is connected to at least a part of the pin portion and is connected to a lower end of the fixing portion to connect the pin portion and the fixing portion to each other.

11. The electrically conductive contact pin of claim 1, further comprising:
a boundary portion provided in a width direction,
wherein the first contact portion is connected to an upper portion of the boundary portion,
the elastic portion is connected to a lower portion of the boundary portion, and
the connecting portion is connected to each side of the boundary portion.

12. The electrically conductive contact pin of claim 1, wherein the fixing portion comprises a protrusion protruding outwardly.

13. The electrically conductive contact pin of claim 1, wherein at least a part of the elastic portion protrudes outwardly below a lower end of the fixing portion, and
at least a part of the first contact portion protrudes outwardly upwardly above an upper end of the fixing portion.

14. The electrically conductive contact pin of claim 1, wherein the elastic portion is formed by alternately connecting a plurality of straight portions and a plurality of curved portions, and
a distance between two straight portions connected to one curved portion does not exceed a distance between opposite sides of the one curved portion.

15-20. (canceled)

21. An electrically conductive contact pin having an overall length in a length direction, an overall thickness in a thickness direction perpendicular to the length direction, and an overall width in a width direction perpendicular to the length direction,
wherein plates are integrally connected to each other form the electrically conductive contact pin, and
an actual width of the plates constituting the electrically conductive contact pin and the overall thickness have a ratio in a range of 1:5 to 1:30.

22. The electrically conductive contact pin of claim 21, wherein the overall thickness and the overall length have a ratio in a range of 1:3 to 1:9, and the overall thickness and the overall width have a ratio in a range of 1:1 to 1:5.

23. The electrically conductive contact pin of claim 21, wherein the actual width of the plates is in a range of 5 μm to 15 μm, and
the overall thickness is in a range of 70 μm to 200 μm.

24. The electrically conductive contact pin of claim 21, wherein the overall length is in a range of 300 μm to 2 mm.

25-29. (canceled)
